(19) United States
(12) Patent Application Publication
(10) Pub. No.: US 2007/0126025 A1
(43) Pub. Date: Jun. 7, 2007

(54) SEMICONDUCTOR DEVICE AND METHOD FOR MANUFACTURING THE SAME

(75) Inventor: Takashi YUDA, Tokyo (JP)

Correspondence Address: RABIN & Berdo, PC, 1101 14TH STREET, NW, SUITE 500, WASHINGTON, DC, 20005, US

(73) Assignee: OKI ELECTRIC INDUSTRY CO., LTD., Tokyo (JP)

(21) Appl. No.: 11/549,960

(22) Filed: Oct. 16, 2006

(30) Foreign Application Priority Data
Dec. 2, 2005 (JP) 2005-349391

(51) Int. Cl. H01L 31/00

(52) U.S. Cl. 257/192

(57) ABSTRACT

A semiconductor device includes a semiconductor substrate, a plurality of first wirings disposed above the semiconductor substrate along a first direction, a diffusion layer that is disposed on the surface of the semiconductor substrate so as to extend along a second direction perpendicular to the first direction and which includes a plurality of first diffusion portions overlapping with the plurality of first wirings, a first conductive film that is disposed between adjacent first diffusion layer portions of the plurality of the first diffusion layer portions disposed along the plurality of first wirings, respectively, in a layer between the semiconductor substrate and the plurality of first wirings, and electrically coupled to the plurality of first wirings, a plurality of sidewall portions, each of which is formed on a lateral side of the first conductive film to be disposed between the first conductive film and its adjacent first diffusion layer portion so as to extend along the diffusion layer, and a second conductive film that has a predetermined thickness and is filled in spaces, each of which is interposed between two adjacent sidewall portions on each of the plurality of first diffusion layer portions, so as to extend along each of the plurality of first diffusion layer portions.

This application claims priority to Japanese Patent Application No. 2005-349391. This entire disclosure of Japanese Patent Application No. 2005-349391 is hereby incorporated herein by reference.

### BACKGROUND OF THE INVENTION

1. Field of the Invention

The present invention relates to a semiconductor device in which a diffusion layer is used as a wiring and a method for manufacturing the same.

A two-bit-per-cell nonvolatile semiconductor memory device has been known in the past. The memory cells thereof comprise two charge storage portions, respectively. For example, this type of nonvolatile semiconductor device is formed as follows. First, an active region that is surrounded by a field oxide film for element isolation is formed on a semiconductor substrate. Then, a gate oxide film, a polysilicon film, a tungsten silicide film (WSi film), an above-gate NSG film, an above-gate nitride film are sequentially formed thereon. Next, the gate oxide film, the polysilicon film, the WSi film, the above-gate NSG film, and the above-gate nitride film are patterned with the use of a resist as a mask. Thus, the gates of cell transistors and peripheral circuit transistors are formed simultaneously. At this time, the gate is patterned in a plurality of lines extending along a first direction in a memory cell region.

Next, LDDs of the cell transistor and the peripheral circuit transistor are formed by ion implantation, and furthermore a NSG film, a silicon nitride film (charge storage film), and a NSG film are formed sequentially. Then, these films are etched back, and thus first sidewalls (charge storage portions) of the cell transistor and the peripheral circuit transistor are formed. Next, an N⁺ diffusion layer (source/drain) of the cell transistor and the peripheral circuit transistor is formed by means of ion implantation with use of the gates and the first sidewalls as masks. At this time, the N⁺ diffusion layer is formed in a line shape along the gates that extend along the first direction. A NSG film is further laminated, and then etch back is performed with respect to it. Thus, a second sidewall is formed outside each of the first sidewalls. Furthermore, a cobalt silicide is formed on the N⁺ diffusion layer with use of the gates, the first sidewalls, and the second sidewalls as masks.

Next, a NSG film is filled in spaces between the second sidewalls, and planarization is performed with respect to the NSG film by means of chemical mechanical polishing (CMP) with the use of the above-gate nitride film as a stopper. Then, the above-gate nitride film is removed, and the above-gate NSG film is removed with use of a resist as a mask. Thus, the WSi film is exposed.

Next, a tungsten film (W film) is formed on the whole surface, and the W film is etched with use of a resist as a mask. Thus, a word line is formed. Furthermore, portions of the WSi film and the polysilicon film, which are not covered with the word line, are removed, and a gate electrode is patterned in an island shape. Next, an intermediate insulation film is formed. Then a contact hole for exposing the N⁺ diffusion layer (source/drain) is formed, and a contact is formed.

In this configuration, the N⁺ diffusion layer is integrally formed with a source/drain of a plurality of cell transistors, and is used as a wiring (diffusion layer wiring).

For example, Japan Patent Application Publication JP-A-06-216393 discloses a memory cell structure in which a diffusion layer is used as a wiring. An object thereof is to reduce the resistance value of a wiring.

In the configuration of the above described conventional nonvolatile semiconductor device, the cobalt silicide is formed in the N⁺ diffusion layer of the cell transistor, and thus resistance is lowered. However, the above described configuration will have a sheet resistance that is ten times or greater as much as that of a metal wiring. For example, the sheet resistance (Rs) of tungsten (W) with a thickness of 300 nm is 0.7 Ω. In addition, the sheet resistance (Rs) of cobalt silicide with a thickness of 6 nm is 10 Ω. Because of this, it is necessary to line a metal wiring in a first metal wiring layer (1M) that is disposed above so that the metal wiring is disposed in parallel with the N⁺ diffusion layer. Accordingly, a problem is caused in that the cell block is formed in a larger size by just that amount.

In addition, a charge storage film is also formed in the peripheral circuit transistor because the cell transistor and the peripheral circuit transistor are formed simultaneously. As a result, the hot carrier resistance of the peripheral circuit transistor will be weakened compared to a case in which no charge storage film is formed.

Furthermore, it is necessary to form a WSi film in the gate electrode of the cell transistor because the cell transistor and the peripheral circuit transistor are formed simultaneously. Because of this, when the gate electrode is etched in an island shape, it is necessary to etch the WSi film and the polysilicon film. In other words, it is necessary to perform etching of a plurality of substances, and thus a problem is caused in that the etching process will be complicated.

### SUMMARY OF THE INVENTION

A semiconductor device in accordance with the present invention comprises (a) a semiconductor substrate, (b) a plurality of first wirings that are disposed above the semiconductor substrate along a first direction, (c) a diffusion layer that is disposed on the surface of the semiconductor substrate so as to extend along a second direction perpendicular to the first direction and includes a plurality of first diffusion layer portions overlapping with the plurality of first wirings, (d) a first conductive film that is disposed between adjacent first diffusion layer portions of the plurality of first diffusion layer portions disposed along the plurality of first wirings, respectively, in a layer between the semiconductor substrate and the plurality of first wirings, and electrically coupled to the plurality of first wirings, (e) a plurality of sidewall portions, each of which is formed on a lateral side of the first conductive film to be disposed between the first conductive film and its adjacent first diffusion layer portion so as to extend along the diffusion layer, and (f) a second conductive film that has a predetermined thickness and is filled in spaces, each of which is interposed between two adjacent sidewall portions on each of the plurality of diffusion layer portions, so as to extend along each of the plurality of first diffusion layer portions.

The first conductive film comprises gate electrodes of memory transistors, for instance. The first diffusion layer portion comprises sources/drains thereof. In addition, the diffusion layer and the second conductive film comprise bit lines, and the first wirings comprise word lines.

In this semiconductor device, the first conductive film is formed in the intersections between the plurality of wirings and linear portions located between adjacent first diffusion layer portions. Each of the sidewall portions is formed on a lateral side of the first conductive film so as to extend along the diffusion layer, and the second conductive film is filled in spaces interposed between two adjacent sidewall portions. It is possible to reduce resistance value of the wiring comprised of the second conductive film and the diffusion layer.

In addition, the semiconductor device has a configuration in which the second conductive film is filled in spaces interposed between two adjacent sidewall portions. Therefore, it is easy to adjust the thickness of the second conductive film. Because of this, it is possible to easily adjust the resistance value of the wirings comprised of the second conductive film and the diffusion layer by adjusting the thickness of the film.

In addition, the electric conductivity of a diffusion layer can be compensated for if metal wirings are formed in an upper layer so that they are disposed along a diffusion layer and contacts are formed between the metal wirings and the diffusion layer in a plurality of positions. In this case, however, there is a possibility that a semiconductor device is formed in a larger size for the purpose of reserving a region for forming the contacts. On the other hand, according to the configuration of the present invention, it is possible to sufficiently compensate for the electric conductivity of the diffusion layer by forming the first conductive film. Therefore, it is not necessary to compensate for the electric conductivity of the diffusion layer by forming upper layer metal wirings. Accordingly, it is possible to prevent the semiconductor device from being formed in a larger size. In addition, the first conductive film is only filled in the spaces interposed between two adjacent sidewall portions. Therefore, there is no possibility that the semiconductor device will be formed in a larger size by forming the first conductive film.

A method for manufacturing a semiconductor device in accordance with the present invention is comprised of the steps of (a) preparing a semiconductor substrate, (b) forming a multi-layer laminated film by sequentially forming a first insulation film, a first conductive film, and a second insulation film on the semiconductor device, (c) patterning the multi-layer laminated film in a pattern including a plurality of linear patterns that extend along a first direction, (d) forming a plurality of sidewall portions on both sides of the plurality of linear patterns so as to extend along each of the plurality of linear patterns, (e) forming a diffusion layer that is disposed outside each of the plurality of sidewall portions on the surface of the semiconductor substrate so as to extend along the plurality of sidewall portions, (f) forming a second conductive film on the diffusion layer so as to extend along the diffusion layer by filling the second conductive film with a predetermined thickness in spaces interposed between two adjacent sidewall portions, (g) forming a third insulation film that is filled in spaces interposed between two adjacent sidewall portions and covers the plurality of linear patterns, (h) exposing the second insulation film of the plurality of linear patterns by performing planarization with respect to the third insulation film so that the vertical level of the third insulation film corresponds to the height of the plurality of sidewall portions, (i) exposing the first conductive film by removing the second insulation film, (j) forming a third conductive film on the first conductive film and the third insulation film, (k) patterning the third conductive film in a plurality of first wirings that extend along a second direction approximately perpendicular to the first direction, and (l) removing portions of the first conductive film of the plurality of linear patterns that are not covered with the plurality of first wirings.

The plurality of linear patterns comprised of the first insulation film, the first conductive film, and the second insulation film comprise the gates of memory transistors, for instance. In addition, the diffusion layer and the second conductive film comprise bit lines, and the third conductive film comprises word lines.

The plurality of sidewall portions are formed on both sides of the plurality of linear patterns extending along the first direction so as to extend along the gate. The diffusion layer is formed in spaces interposed between two adjacent sidewall portions so as to extend along the plurality of linear patterns, and the second conductive film is formed on the diffusion layer so as to extend along the diffusion layer. Thus, wirings comprised of the diffusion layer and the second conductive film are formed. According to this manufacturing method, it is possible to reduce resistance value of the wirings comprised of the diffusion layer and the second conductive film.

In addition, the second conductive film is filled in spaces interposed between two adjacent sidewall portions. Therefore, it is easy to adjust the thickness of the first conductive film, and furthermore it is possible to easily adjust the resistance value of the wirings comprised of the diffusion layer and the second conductive film by adjusting the thickness of the film.

In addition, the second conductive film is only filled in the spaces interposed between two adjacent sidewall portions. Therefore, it is not necessary to separately reserve a region for forming the second conductive film, and thus it is possible to prevent the semiconductor device from being formed in a larger size. Furthermore, it is possible to sufficiently compensate for the electric conductivity of the diffusion layer by forming the second conductive film. Therefore, it is not necessary to compensate for the electric conductivity of the diffusion layer by forming upper layer metal wirings. Accordingly, it is possible to prevent the semiconductor device from being formed in a larger size.

Another method for manufacturing a semiconductor device in accordance with the present invention is comprised of the steps of (a) preparing a semiconductor substrate comprising a memory cell region in which memory cell transistors are formed and a peripheral circuit region in which peripheral circuit transistors are formed, (b) forming a fifth insulation film so as to cover the peripheral circuit region, (c) forming a multi-layer laminated film by sequentially forming a first insulation film, a first conductive film, a second insulation film on the memory cell region, (d) patterning the multi-layer laminated film in a pattern including a plurality of linear patterns that extend along a first direction, (e) forming a plurality of sidewall portions on both sides of the plurality of line patterns and extending along each of the plurality of linear patterns, (f) forming a plurality of diffusion layers on the outside of each of the plurality of sidewall portions on the surface of the semiconductor substrate so as to extend along the plurality of sidewall portions, (g) forming a second conductive film on the diffusion layer so as to extend along the diffusion layer by filling the second conductive film with a predetermined thickness in spaces interposed between two adjacent sidewall portions, (h) forming a third insulation film that fills in spaces interposed between two adjacent sidewall portions and covers the plurality of linear patterns for the purpose of covering the memory cell region, (i) removing the fifth insulation film that covers the peripheral circuit region, (j) forming peripheral circuit transistors in the peripheral circuit region, (k) forming a fourth insulation film on the peripheral circuit transistor and the third insulation film, (l) performing planarization with respect to the fourth insulation film and the third insulation film so that the vertical levels of the fourth insulation film and the third insulation film correspond to the height of the plurality of sidewall portions for the purpose of exposing the second insulation film of the plurality of linear patterns, (m) removing the second insulation film for the purpose of exposing the first conductive film, (n) forming a third conductive film on the first conductive film and the third insulation film, (o) patterning the third conductive film in a plurality of first wirings that extend along a second direction approximately perpendicular to the first direction, and (p) removing portions of the first conductive film of the plurality of linear patterns that are not covered with the plurality of first wirings.

According to this manufacturing method, it is possible to sufficiently compensate for the electric conductivity of the diffusion layer by the second conductive film that is filled in spaces interposed between two adjacent sidewall portions. In other words, it is possible to reduce the resistance value of the wirings comprised of the diffusion layer and the second conductive film. In addition, the second conductive film is filled in the spaces interposed between two adjacent sidewall portions. Therefore, it is easy to adjust the thickness of the first conductive film, and furthermore it is possible to easily adjust the resistance value of the wirings comprised of the diffusion layer and the second conductive film by adjusting the thickness of the film. In addition, the second conductive film is only filled in the spaces interposed between two adjacent sidewall portions. Therefore, it is not necessary to separately reserve a region for forming the second conductive film, and thus it is possible to prevent the semiconductor device from being formed in a larger size. Furthermore, it is possible to sufficiently compensate for the electric conductivity of the diffusion layer by forming the second conductive film. Therefore, it is not necessary to compensate for the electric conductivity of the diffusion layer by forming upper layer metal wirings. Accordingly, it is possible to prevent the semiconductor device from being formed in a larger size.

According to this manufacturing method, the memory cell region and the peripheral circuit region are separately patterned. Therefore, it is possible not to form a charge storage film in each of the peripheral circuit transistors. Because of this, it is possible to prevent the hot carrier resistance of the peripheral circuit transistor from being weakened.

According to this manufacturing method, the memory cell region and the peripheral circuit region are separately patterned. Therefore, it is possible not to form a silicide in the gate electrodes in the memory cell transistors, respectively. Because of this, it will be easy to perform a etching step of the gate electrode.

Furthermore, another method for manufacturing a semiconductor device in accordance with the present invention is comprised of the steps of (a) preparing a semiconductor substrate comprising a memory cell region in which memory cell transistors are formed and a peripheral circuit region in which peripheral circuit transistors are formed, (b) forming a multi-layer laminated film by sequentially forming a first insulation film, a first conductive film, a second insulation film in the memory cell region and the peripheral circuit region, (c) patterning the multi-layer laminated film in a pattern including a plurality of linear patterns that extend along a first direction in the memory cell region, (d) forming a plurality of sidewall portion on both sides of the plurality of linear patterns and extending along each of the plurality of linear patterns, (e) forming a diffusion layer on the outside of each of the plurality of the sidewall portions on the surface of the semiconductor substrate so as to extend along the plurality of the sidewall portions, (f) forming a second conductive film on the diffusion layer so as to extend along the diffusion layer by filling the second conductive film with a predetermined thickness in spaces interposed between two adjacent sidewall portions, (g) forming a third insulation film that fills spaces interposed between two adjacent sidewall portions and covers the plurality of linear patterns for the purpose of covering the memory cell region, (h) forming peripheral circuit transistors by patterning the multi-layer laminated film in the peripheral circuit region, (i) forming a fourth insulation film on the peripheral circuit transistor and the third insulation film, (j) performing planarization with respect to the fourth insulation film and the third insulation film so that the vertical levels of the fourth insulation film and the third insulation film correspond to the height of the plurality of sidewall portions for the purpose of exposing the second insulation film of the plurality of linear patterns, (k) removing the second insulation film for the purpose of exposing the first conductive film, (l) forming a third conductive film on the first conductive film and the third insulation film, (m) patterning the third conductive film in a plurality of first wirings that extend along a second direction approximately perpendicular to the first direction, and (n) removing portions of the first conductive film of the plurality of linear patterns that are not covered with the plurality of first wirings.

According to this manufacturing method, it is possible to sufficiently compensate for the electric conductivity of the diffusion layer by the second conductive film that is filled in the spaces interposed between two adjacent sidewall portions. In other words, it is possible to reduce the resistance value of the wirings comprised of the diffusion layer and the second conductive film. In addition, the second conductive film is filled in the spaces interposed between two adjacent sidewall portions. Therefore, it is easy to adjust the thickness of the first conductive film, and furthermore it is possible to easily adjust the resistance value of the wirings comprised of the diffusion layer and the second conductive film by adjusting the thickness of the film. In addition, the second conductive film is only filled in the spaces interposed between two adjacent sidewall portions. Therefore, it is not necessary to separately reserve a region for forming the second conductive film, and thus it is possible to prevent the semiconductor device from being formed in a larger size. Furthermore, it is possible to sufficiently compensate for the electric conductivity of the diffusion layer by forming the second conductive film. Therefore, it is not necessary to compensate for the electric conductivity of the diffusion layer by forming upper layer metal wirings. Accordingly, it is possible to prevent the semiconductor device from being formed in a larger size.

According to this manufacturing method, the memory cell region and the peripheral circuit region are separately patterned. Therefore, it is possible not to form a charge storage film in each of the peripheral circuit transistors. Because of this, it is possible to prevent the hot carrier resistance of the peripheral circuit transistor from being weakened.

In addition, the multi-layer laminated film comprised of the first insulation film, the first conductive film, and the second insulation film is formed in the memory cell region and the peripheral circuit region, and the gates of the memory cell transistors and those of the peripheral circuit transistors are formed in this multi-layer laminated film. In other words, the transistors of the memory cell region and those of the peripheral circuit region are formed in the common multi-layer laminated film. Therefore, it is possible to reduce the number of steps for forming the gates.

According to the present invention, it is possible to prevent a semiconductor device in which a diffusion layer is used as a wiring from being formed in a larger size and to reduce the resistance value of a diffusion layer wiring therein.

These and other objects, features, aspects, and advantages of the present invention will become apparent to those skilled in the art from the following detailed description, which, taken in conjunction with the annexed drawings, discloses a preferred embodiment of the present invention.

### BRIEF DESCRIPTION OF THE DRAWINGS

Referring now to the attached drawings which form a part of this original disclosure:

FIG. 1 is a schematic plan view showing a portion of a configuration of a semiconductor device in accordance with a first embodiment of the present invention;

FIGS. 2A to 2C are process diagrams showing a manufacturing method of the semiconductor device in accordance with the first embodiment of the present invention, which are viewed from a cross-section A-A thereof in FIG. 1;

FIGS. 3A to 3C are process diagrams showing a manufacturing method of the semiconductor device in accordance with the first embodiment of the present invention, which are viewed from the cross-section A-A thereof in FIG. 1;

FIGS. 4A to 4C are process diagrams showing a manufacturing method of the semiconductor device in accordance with the first embodiment of the present invention, which are viewed from the cross-section A-A thereof in FIG. 1;

FIGS. 5A and 5B are process diagrams showing a manufacturing method of the semiconductor device in accordance with the first embodiment of the present invention, which are viewed from the cross-section A-A thereof in FIG. 1;

FIGS. 6A to 6C are process diagrams showing a manufacturing method of the semiconductor device in accordance with the first embodiment of the present invention, which are viewed from the cross-section A-A thereof in FIG. 1;

FIGS. 7A and 7B are process diagrams showing a manufacturing method of the semiconductor device in accordance with the first embodiment of the present invention, which are viewed from the cross-section A-A thereof in FIG. 1;

FIGS. 8A to 8C are process diagrams showing a manufacturing method of the semiconductor device in accordance with the first embodiment of the present invention, which are viewed from a cross-section C-C thereof in FIG. 1;

FIGS. 9A to 9C are process diagrams showing a manufacturing method of the semiconductor device in accordance with the first embodiment of the present invention, which are viewed from the cross-section B-B thereof in FIG. 1;

FIGS. 10A to 10C are process diagrams showing a manufacturing method of the semiconductor device in accordance with the first embodiment of the present invention, which are viewed from the cross-section B-B thereof in FIG. 1;

FIGS. 11A to 11C are process diagrams showing a manufacturing method of the semiconductor device in accordance with the first embodiment of the present invention, which are viewed from the cross-section B-B thereof in FIG. 1;

FIG. 12 is a process diagram showing a manufacturing method of the semiconductor device in accordance with the first embodiment of the present invention, which is viewed from the cross-section B-B thereof in FIG. 1;

FIGS. 13A to 13C are process diagrams showing a manufacturing method of the semiconductor device in accordance with a second embodiment of the present invention, which are viewed from the cross-section A-A thereof in FIG. 1;

FIGS. 14A to 14C are process diagrams showing a manufacturing method of the semiconductor device in accordance with the second embodiment of the present invention, which are viewed from the cross-section A-A thereof in FIG. 1;

FIGS. 15A to 15C are process diagrams showing a manufacturing method of the semiconductor device in accordance with a second embodiment of the present invention, which are viewed from the cross-section A-A thereof in FIG. 1;

FIGS. 16A to 16C are process diagrams showing a manufacturing method of the semiconductor device in accordance with the second embodiment of the present invention, which are viewed from the cross-section A-A thereof in FIG. 1;

FIGS. 17A and 17B are process diagrams showing a manufacturing method of the semiconductor device in accordance with the second embodiment of the present invention, which are viewed from the cross-section A-A thereof in FIG. 1;

FIG. 18 is a process diagram showing a manufacturing method of the semiconductor device in accordance with the second embodiment of the present invention, which is viewed from the cross-section A-A thereof in FIG. 1;

FIGS. 19A to 19C are process diagrams showing a manufacturing method of the semiconductor device in accordance with the second embodiment of the present invention, which are viewed from the cross-section C-C thereof in FIG. 1;

FIGS. 20A to 20C are process diagrams showing a manufacturing method of the semiconductor device in accordance with the second embodiment of the present invention, which are viewed from the cross-section B-B thereof in FIG. 1;

FIGS. 21A to 21C are process diagrams showing a manufacturing method of the semiconductor device in accordance with the second embodiment of the present invention, which are viewed from the cross-section B-B thereof in FIG. 1; and

FIGS. 22A and 22B are process diagrams showing a manufacturing method of the semiconductor device in accordance with the second embodiment of the present invention, which are viewed from the cross-section B-B thereof in FIG. 1.

### DETAILED DESCRIPTION OF THE PREFERRED EMBODIMENTS

Selected embodiments of the present invention will now be explained with reference to the drawings. It will be apparent to those skilled in the art from this disclosure that the following descriptions of the embodiments of the present invention are provided for illustration only and not for the purpose of limiting the invention as defined by the appended claims and their equivalents.

### First Embodiment

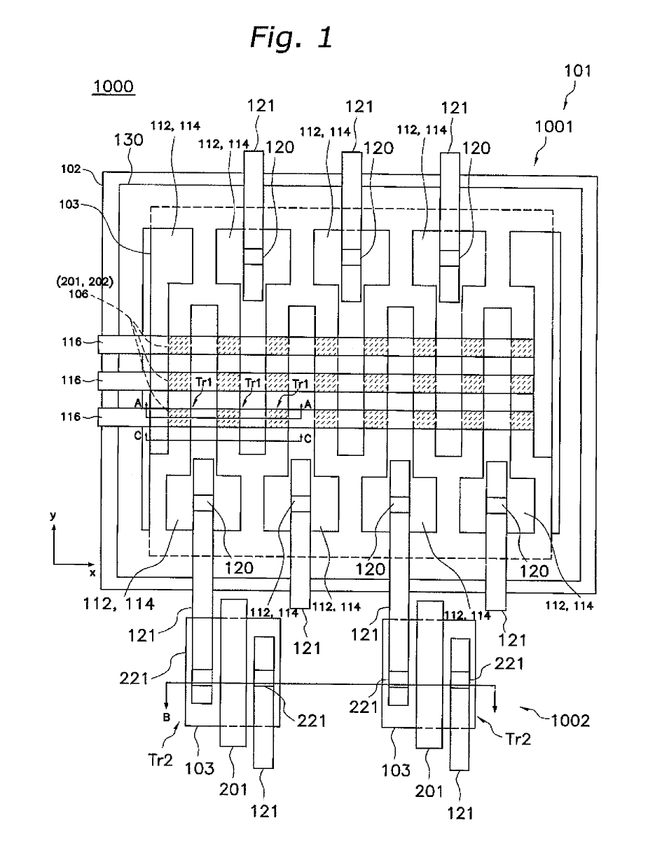

FIG. 1 is a plan view showing the configuration of a semiconductor device 1000 in accordance with the first embodiment of the present invention. Note that portions of hatching in a cross section of each of the after-mentioned drawings will be omitted for the purpose of clarifying the configuration thereof.

A semiconductor device 1000 shown in FIG. 1 comprises a memory cell region 1001 and a peripheral circuit region 1002. The semiconductor device 1000 is a two-bit-per-cell nonvolatile semiconductor device. In other words, each memory cell in the semiconductor device 1000 comprises two charge storage portions.

An active region 103 is formed in the memory cell region 1001 and is surrounded by a field insulation film 102. A plurality of cell transistors Tr1 are formed in the active region 103.

In addition, a plurality of word lines 116 are formed in the memory cell region 1001 in a x-direction, and a plurality of portions of N⁺ diffusion layer 112 are formed therein in a y-direction.

Furthermore, a gate pattern 130 is formed in the memory cell region 1001 so that it surrounds the active region 103, and gate electrodes (polysilicon films) 106 are formed in regions in which the gate pattern 130 and the word lines 116 overlap with each other.

The gate pattern 130 is formed so that the plurality of portions of N⁺ diffusion layer 112 are separated from each other. In addition, the gate pattern 130 is formed to surround the active region 103. With this configuration, the semiconductor device 1000 is configured so that each of the diffusion layers is isolated.

A plurality of contacts 120 are formed above the extended members (described below) of the plurality of portions of N⁺ diffusion layer 112.

The plurality of portions of N⁺ diffusion layer 112 are disposed along the y-direction so that they cross the plurality of word lines 116. Note that after-mentioned LDDs 108 are also disposed along the y-direction as with the plurality of portions of N⁺ diffusion layer 112. Then, the plurality of portions of N⁺ diffusion layer 112 connect the sources/drains of the plurality of cell transistors Tr1 disposed along the y-direction to each other.

Each of the plurality of portions of N⁺ diffusion layer 112 has an extended member whose width in the x-direction is larger than that of the other members thereof in the x-direction. An after-mentioned contact 120 is formed in the extended member.

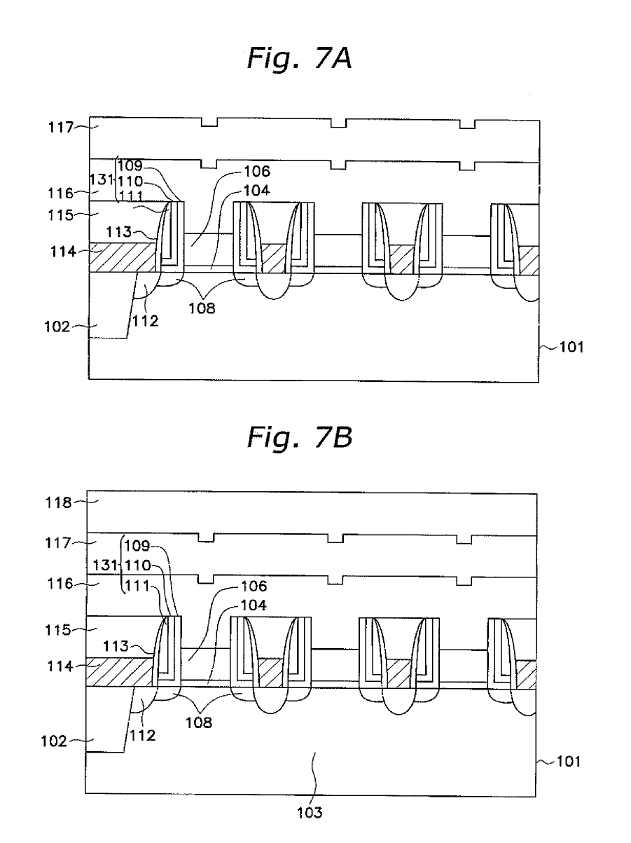

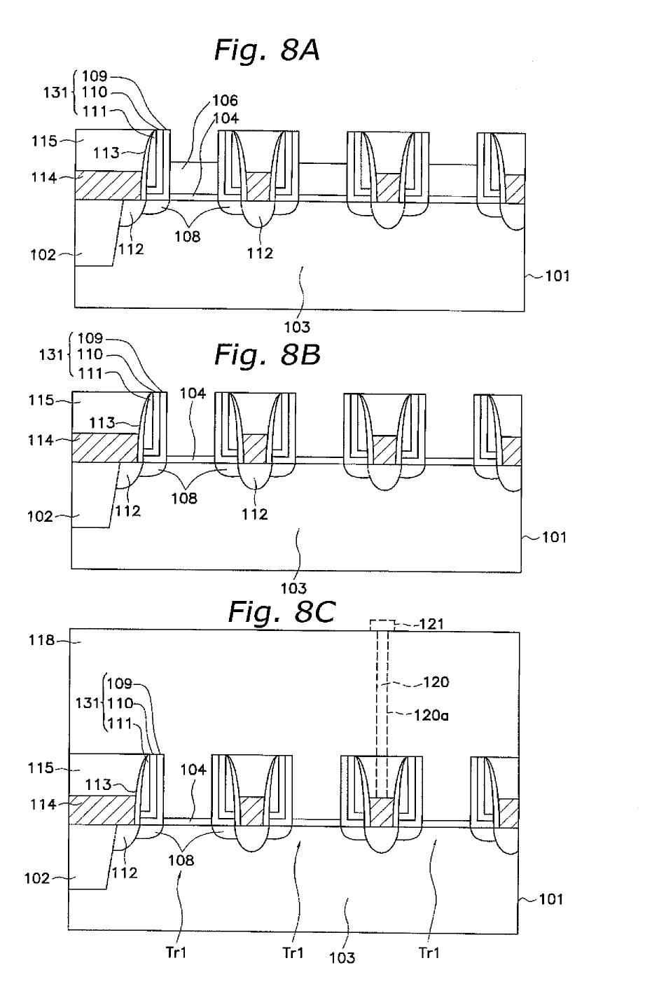

FIG. 7B is a diagram showing a cross-section indicated by Arrow A-A in FIG. 1. On the other hand, FIG. 8C is a diagram showing a cross-section indicated by Arrow C-C in FIG. 1.

In FIGS. 7B and 8C, the gate pattern 130 is a pattern that shows regions delimited inside pairs of a sidewall 131 and a sidewall 113. The gate pattern 130 has a pattern that is the same as the disposition pattern of the gate insulation film 104.

In a manufacturing process of the semiconductor device, portions of the polysilicon film 106 shown in FIG. 1 are temporarily formed as gate electrodes in the gate pattern 130. Then, in a later process, portions of the polysilicon film 106 that do not overlap with the plurality of word lines 116 will be removed. Therefore, the polysilicon film 106 is shown immediately below the word line 116 in FIG. 7B. In addition, an intermediate insulation film 118 is filled instead of the polysilicon film 106 in FIG. 8C.

In addition, the polysilicon film 106 is formed to be disposed immediately below the word line 116 in FIG. 7B. More specifically, it is formed immediately above the gate insulation film 104. Pairs of the sidewall 131 and the sidewall 113 are disposed on both sides of the gate insulation film 104 and the polysilicon film 106.

In addition, no polysilicon film 106 is disposed on portions of the gate insulation film 104 that are not disposed below the word line 116 in FIG. 8C. Instead of this, the intermediate insulation film 118 is filled. Pairs of the sidewall 131 and the sidewall 113 are disposed on both sides of the gate insulation film 104. The sidewall 131 includes a charge storage film 110 and a silicon oxide film 111. The charge storage film 110 is comprised of an L-shaped silicon oxide film 109 and an L-shaped silicon nitride film. On the other hand, the silicon oxide film 111 is formed to fill the L-shaped portion of the charge storage film 110 therewith.

The sidewall 131 is configured by interposing the charge storage film 110 between the silicon oxide film 109 and the silicon oxide film 111, both of which comprise a charge barrier film. In addition, the sidewall 131 comprises a charge retention portion (charge storage portion) for storing electrons in the charge storage film 110. On the other hand, the sidewall 113 is comprised of a silicon oxide film (nondoped silicate glass film: NSG film), for instance.

In FIG. 7B, the sidewall 113 is disposed between the sidewall 131 and a buried conductive film 114. With this disposition, the sidewall 131 and the buried conductive film 114 are isolated from each other. The buried conductive film 114 and the charge storage film 110 that forms a portion of each of a plurality of sidewalls 131 are electrically isolated from each other through the sidewall 113.

In addition, the sidewall 131 is formed to be disposed along an inner brim portion (opening) of the gate pattern 130 shown in FIG. 1. The sidewall 131 is disposed to surround each of the portions of the N⁺ diffusion layer 112.

In FIGS. 7B and 8C, the LDDs 108 that function as a lightly-doped diffusion layer are formed to be disposed below each of the sidewalls 131. In addition, the LDDs 108 are formed to be disposed along the portions of the N⁺ diffusion layer 112.

Furthermore, in FIGS. 7B and 8C, the portions of N⁺ diffusion layer 112 are formed on both sides of the sidewall 131. In addition, the portions of the N⁺ diffusion layer 112 are formed below the gate insulation film 104 to sandwich the LDDs 108. In addition, the portions of the N⁺ diffusion layer 112 are interposed between sidewalls 131 of adjacent cell transistors Tr1. The N⁺ diffusion layers 112 are to be surrounded by the sidewalls 131. Furthermore, as shown in FIG. 1, the portions of the N⁺ diffusion layer 112 are formed in the openings of the disposition pattern of the gate insulation film 104. The width of the portions of the N⁺ diffusion layers 112 in the x-direction will be smaller than that of the opening of the gate pattern 131, and the difference between them corresponds to the width of the sidewall 131. Note that the portions of the N⁺ diffusion layer 112 comprise sources/drains of the cell transistors Tr1 on both sides of the polysilicon film 106 as shown in FIGS. 1 and 7B.

Furthermore, in FIGS. 7B and 8C, the buried conductive film 114 is filled to be disposed between pairs of the sidewall 131 and the sidewall 113. In addition, the buried conductive film 114 is disposed on the N⁺ diffusion layer 112. The buried conductive film 114 is comprised of a tungsten film, for instance. As shown in FIG. 1, each portion of the buried conductive film 114 is formed to be disposed along each portion of the N⁺ diffusion layer 112 in the y-direction. Each portion of the N⁺ diffusion layer 112 and each portion of the buried conductive film 114 comprise a bit line. Thus, electrical conductivity of the buried conductive film 116 can be sufficiently compensated for by disposing the buried conductive film 114. Therefore, it is possible to greatly reduce the resistance of a wiring comprised of each portion of the N⁺ diffusion layer 112 and that of the buried conductive film 114.

A buried insulation film 115 is formed to be disposed immediately above the buried conductive film 114. The buried insulation film 115 is formed to have approximately the same vertical level as that of the sidewall 131 and the sidewall 113. Thus it is configured to completely bury these sidewalls. The buried insulation film 115 is formed above the N⁺ diffusion layer 112 to be disposed along the N⁺ diffusion layer 112. The buried conductive film 114 and the buried insulation film 115 are configured to prevent formation of a step between the N⁺ diffusion layer 112 and the pair of the sidewall 131 and the sidewall 113.

In FIG. 7B, the word line 116 is formed to prevent formation of a step between the polysilicon film 106 and the sidewall 131, and is coupled to the polysilicon film 106. The word line 116 is also disposed immediately above the buried insulation film 115. The word line 116 extends along a plurality of portions of the polysilicon film 106 disposed in the x-direction as shown in FIG. 1. Because of this, the plurality of portions of polysilicon film 106 disposed in the x-direction are electrically coupled to each other through the word line 116. A hard mask 117 comprised of a silicon oxide film, which was used for processing a word line, remains on the word line 116. However, the hard mask 117 may be removed.

In FIG. 8C, the polysilicon film 106 is removed in the portions other than the portions below the word line 116. The buried conductive film 118 is filled in openings formed by a step between the gate insulation film 104 and the sidewall 131. The intermediate insulation film 118 is formed in the whole of the memory cell region 1001 and the peripheral circuit region 1002. As shown in FIG. 7B, the intermediate insulation film 118 is formed to cover the hard mask 117 disposed immediately on the word line 116. Furthermore, as shown in FIG. 8C, the intermediate insulation film 118 is formed to be disposed on the gate insulation film 104 and the buried insulation film 115.

In addition, a contact 120 is formed by filling a conductive film into a contact hole 120a as shown in FIG. 8C. The contact 120 is formed after the contact hole 120a is formed in the intermediate insulation film 118 and the buried insulation film 115, and thus the buried conductive film 114 is exposed. The contact 120 is electrically coupled to the N⁺ diffusion layer 112 through the buried conductive film 114. As shown in FIG. 1, a plurality of contacts 120 are alternately disposed on the positive direction side of the y-axis and the negative direction side thereof. In addition, each of the plurality of contacts 120 is disposed in each of the plurality of portions of the N⁺ diffusion layer 112. Because of this, the contacts 120 in adjacent portions of the N⁺ diffusion layer 112 are arranged in the opposite sides from each other. In addition, each of 1M wirings 121 are integrally formed with each of the contacts 120 as shown in FIGS. 1 and 8C. Each of the 1M wirings 121 is formed to be disposed on the intermediate film 118 shown in FIGS. 7B and 8C. The 1M wiring 121 electrically couples each of the portions of the N⁺ diffusion layer 112 and a peripheral circuit transistor Tr2 in the peripheral circuit region 1002. As shown in FIG. 1, the extended member of each of the plurality of portions of the N⁺ diffusion layer 112, which is formed in the vicinity of the edge portion thereof, is disposed on the outside of the plurality of word lines 116. The contacts 120 are formed on the outside of the plurality of word lines 116.

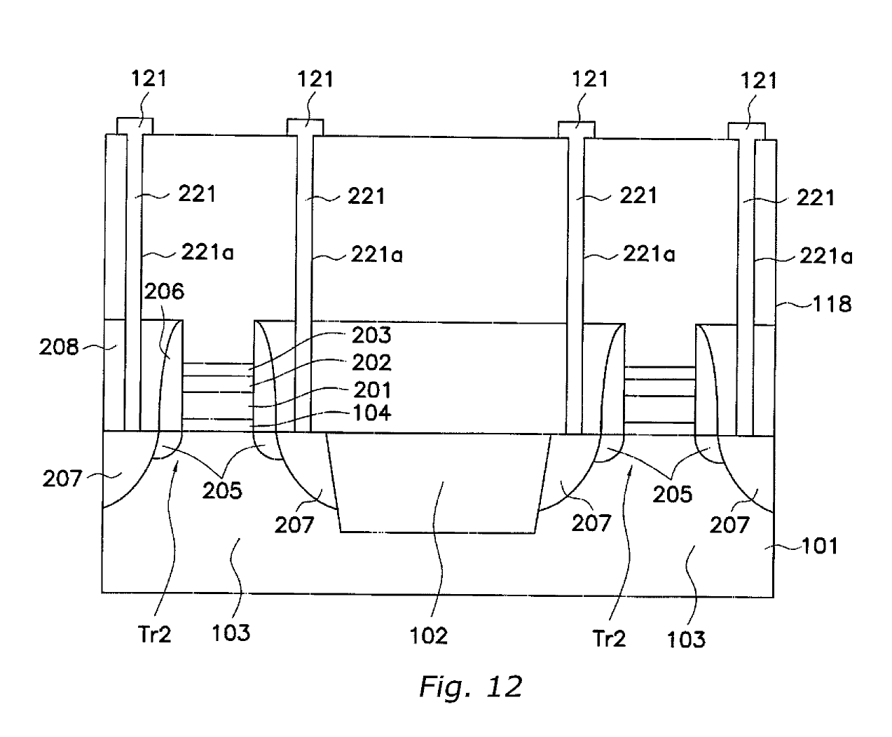

FIG. 12 is a cross-section diagram indicated by Arrow B-B of the semiconductor device 1000 shown in FIG. 1.

In FIGS. 1 and 12, an active region 103 is also delimited by the field insulation film 102 in the peripheral circuit region 1002. Gates and peripheral circuit transistors Tr2 are formed in the active region 103. Each of the above described gates is comprised of an insulation film 104, a polysilicon film 201, and a WSi film 202. Each of the peripheral circuit transistors Tr2 is comprised of an N⁺ diffusion layer 207 functioning as a source/drain.

The gate insulation film 104, the polysilicon film 201, the WSi film 202, and the above-gate insulation film 203 are sequentially laminated on the semiconductor substrate 101 in the active region 103 of the peripheral circuit region 1002. In addition, sidewalls 206 are formed on both sides of the gate insulation film 104, the polysilicon film 201, the WSi film 202, and the above-gate insulation film 203.

The sidewalls 206 are formed to have a height higher than the vertical level of the upper surface of the above-gate insulation film 203. Thus, a step is formed between the sidewalls 206 and the above-gate insulation film 203. Then, LDDs 205 are formed below the sidewalls 206 so that regions located below the gate insulation film 104 are interposed between the LDDs 205.

The N⁺ diffusion layer 207 is formed so that the regions located below the gate insulation film 104 and the sidewalls 206 are interposed between portions of the N⁺ diffusion layer 207. A buried insulation film 208 is formed between adjacent peripheral circuit transistors Tr2. The buried insulation film 208 is formed to have height approximately the same as that of the sidewall 206. The intermediate insulation film 118 is formed to be disposed on the buried insulation film 208 and the space located on the above-gate insulation film 203 on the inner side of the sidewall 206. In addition, contact holes 221a are formed in the intermediate insulation film 118 and the buried insulation film 208 for the purpose of exposing the plurality of portions of the N⁺ diffusion layer 207. In addition, a conductive film such as aluminum (Al) is filled in the contact holes 221a, and thus contacts 221 are formed. The contacts 221 are integrally formed with the 1M wirings 121.

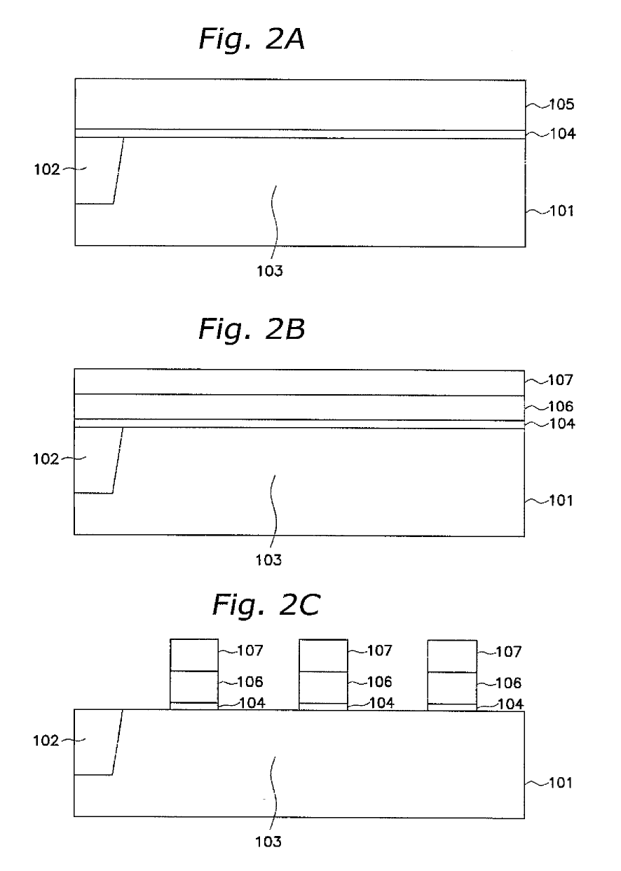

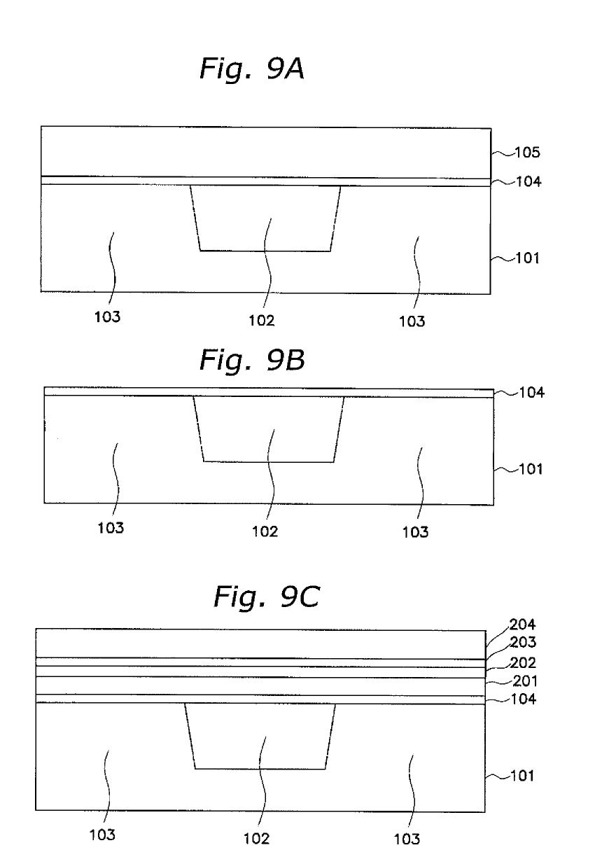

Next, a manufacturing method of a semiconductor device 1000 in accordance with the present embodiment will be hereinafter explained. FIGS. 2A to 2C, 3A to 3C, 4A to 4C, 5A and 5B, 6A to 6C, 7A and 7B, 8A to 8C, 9A to 9C, 10A to 10C, 11A to 11C, and 12 are process diagrams showing a manufacturing method of the semiconductor device 1000. Note that FIGS. 2A to 2C, 3A to 3C, 4A to 4C, 5A and 5B, 6A to 6C, and 7A and 7B are process diagrams of the semiconductor device 1000 viewed from a cross-section A-A thereof shown in FIG. 1. FIGS. 8A to 8C are process diagrams thereof viewed from a cross-section C-C thereof shown in FIG. 1. FIGS. 9A to 9C, 10A to 10C, 11A to 11C, and 12 are process diagrams thereof viewed from a cross-section B-B thereof shown in FIG. 1.

First, steps of a manufacturing process shown in FIGS. 2A and 9A will be explained.

A semiconductor substrate 101 made of silicon is prepared, and a field insulation film 102 is formed in the semiconductor substrate 101 by means of a local oxidation of silicon (LOCOS) method or a shallow trench isolation (STI) method. Thus, an active region 103 that is surrounded by the field insulation film 102 is formed. Note that the semiconductor substrate 101 may be a bulk substrate, a silicon-on-insulator (SOI) substrate, or a silicon-on-sapphire (SOS) substrate.

Next, surface of the semiconductor substrate 101 is thermally oxidized, and thus a gate insulation film 104 comprised of a silicon oxide film with a thickness of 10 nm, for instance, is formed on the surface thereof.

The gate insulation film 104 is formed on the surface of the semiconductor substrate 101. The gate insulation film 104 may be formed by means of a chemical vapor deposition (CVD) method.

Next, a silicon nitride film 105 with a thickness of 20 to 30 nm is formed on the gate insulation film 104. The silicon nitride film 105 is also formed on the whole of the surface of the semiconductor substrate 101. The silicon nitride film 105 can be formed by means of the CVD method, for instance. The conditions of the CVD method are set as follows. For example, the gas flow rates of NH₃ and SiH₂Cl₂ are set to be 1000 and 100 sccm, respectively. The chamber pressure is set to be 0.35 Torr (i.e., 46.7 Pa).

Next, a resist is formed on the silicon nitride film 105 so that it covers a peripheral circuit region 1002. Then, the silicon nitride film 105 in a memory cell region 1001 is removed with use of this resist as a mask. Thus, the gate insulation film 104 is exposed in the memory cell region 1001. The silicon nitride film 105 is removed by means of dry etching, for instance. The dry etching conditions are set as follows. For example, the gas flow rates of CF₄, CH₂F₂, and He are set to be 45, 30, and 100 sccm, respectively. The chamber pressure is set to be 10 mTorr (i.e., 1.33 Pa). The RF powers of the upper and lower portions are set to be 900 and 80 W, respectively.

Next, subsequent steps of the manufacturing method of the semiconductor device 1000 will be hereinafter explained. Here, a cell transistor will be formed in the memory cell region 1001 while the peripheral circuit region 1002 is covered with the silicon nitride film 105 functioning as a mask.

In a step shown in FIG. 2B, a polysilicon film (gate electrode) 106 with a thickness of 100 nm and a silicon nitride film 107 with a thickness of 150 nm are sequentially formed on the gate insulation film 104, for instance. The polysilicon film 106 is formed by means of the CVD method, for instance. The conditions of the CVD method are set as follows. For example, the gas flow rate of SiH₄ is set to be 250 sccm. The chamber pressure is set to be 0.20 Torr (i.e., 26.7 Pa). The silicon nitride film 107 is formed by means of the CVD method, for instance. The conditions of the CVD method are set as follows. For example, the gas flow rates of NH₃ and SiH₂Cl₂ are set to be 1000 and 100 sccm, respectively. The chamber pressure is set to be 0.35 Torr (i.e., 46.7 Pa). The silicon nitride film 107 functions as a stopper when an after-mentioned chemical mechanical polishing (CMP) is performed.

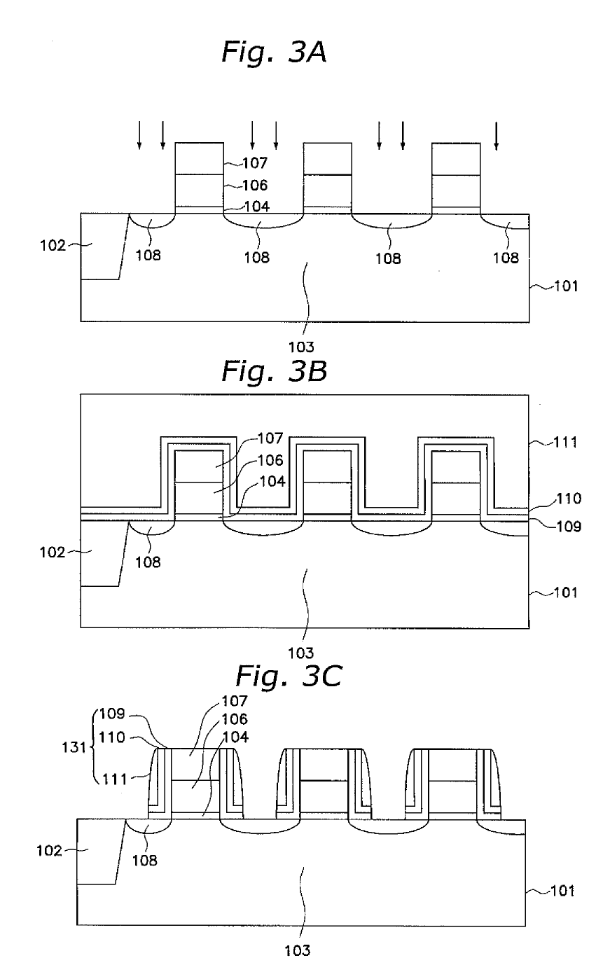

In a step shown in FIG. 2C, a resist pattern of a gate pattern 130 shown in FIG. 1 is formed on the silicon nitride film 107 shown in FIG. 2B. The silicon nitride film 107, the polysilicon film 106, and the gate insulation film 104 are patterned in the shape of the gate pattern 130 with use of this resist pattern as a mask. Thus, the gates, each of which are comprised of the polysilicon film 106 and the gate insulation film 104, are formed as shown in FIG. 3C. At this time, portions of the surface of the semiconductor substrate 101 are exposed on both sides of portions of the silicon nitride film 107 and those of the polysilicon film 106. The exposed portions will be openings of the gate pattern 130 shown in FIG. 1.

The silicon nitride film 107 is removed by means of dry etching, for instance. The dry etching conditions are set as follows. For example, the gas flow rates of CF₄, CH₂F₂, and He are set to be 45, 30, and 100 sccm, respectively. The chamber pressure is set to be 10 mTorr (i.e., 1.33 Pa). The RF powers of upper and lower portions are set to be 900 and 80 W, respectively. The polysilicon film 106 is removed by means of dry etching, for instance. The dry etching conditions are set as follows. For example, the gas flow rates of HBr and O₂ are set to be 100 and 3 sccm, respectively. The chamber pressure is set to be 5 mTorr (i.e., 0.667 Pa). The RF powers of upper and lower portions are set to be 350 and 30 W, respectively. The gate insulation film 104 is removed by means of dry etching, for instance. The dry etching conditions are set as follows. For example, the gas flow rates of CHF₃ and CO are set to be 30 and 170 sccm, respectively. The chamber pressure is set to be 40 mTorr (i.e., 5.33 Pa). The RF power is set to be 800 W.

In a step shown in FIG. 3A, firstly, an oxide film functioning as a mask (not shown in the figure) with a thickness of approximately 10 nm, for instance, is formed by means of thermal oxidation or the CVD method so that it covers the exposed portions of the semiconductor substrate 101. Then, ion implantation is performed with respect to portions of the surface of the semiconductor substrate 101 that are located on both sides of portions of the silicon nitride film 107 and those of the polysilicon film 106 through the oxide film functioning as a mask for the purpose of forming LDDs. In the ion implantation, for example, arsenic (As) is implanted under conditions in which the acceleration energy is 30 keV and the dose amount is 1×10¹³ cm⁻². Then, thermal treatment is performed with respect to the semiconductor substrate 101, and the implanted ions are diffused. Thus, LDDs 108 are formed. The LDDs 108 are formed in the shape of the openings in the gate pattern 130 shown in FIG. 1. Then, the oxide film functioning as a mask is removed.

In a step shown in FIG. 3B, a silicon oxide film 109 with a thickness of 10 nm, a silicon nitride film (charge storage film) 110 with a thickness of 8 nm, and a silicon oxide film 111, for instance, are sequentially formed on the surface of the semiconductor substrate 101. The silicon oxide film 109 is formed by means of the CVD method or thermal oxidation. The charge storage film 110 is formed by means of the CVD method, for instance. The conditions of the CVD method are set as follows. For example, the gas flow rates of NH₃ and SiH₂Cl₂ are set to be 1000 and 100 sccm, respectively. The chamber pressure is set to be 0.35 Torr (i.e., 46.7 Pa). The silicon oxide film 111 is formed by depositing non-doped silicate glass (NSG) by means of the CVD method, for instance. The conditions of the CVD method are set as follows. The gas flow rate of TEOS (Si(OC₂H₆)₄) is set to be 150 sccm. The chamber pressure is set to be 0.3 Torr (i.e., 40 Pa).

In a step shown in FIG. 3C, the silicon oxide film 111, the charge storage film 110, and the silicon oxide film 109 are etched back so that the surface of the semiconductor substrate 101 is exposed. Next, a sidewall 131 that is comprised of the silicon oxide film 109, the charge storage film 110, and the silicon oxide film 111 with a thickness of 50 nm is formed. At this time, the area of the exposed portions of the semiconductor substrate 101 will be smaller than that of the openings in the gate pattern 130 shown in FIG. 1. The sidewall 131 is formed along the inner brim portion of the openings in the gate pattern 130, and thus the area of the exposed portions of the semiconductor substrate 101 will be smaller than the openings by just that amount. The silicon oxide film 109, the charge storage film 110, and the silicon oxide film 111 are etched back by means of dry etching, for instance. The dry etching conditions are set as follows. For example, the gas flow rates of CHF₃ and CO are set to be 30 and 170 sccm, respectively. The chamber pressure is set to be 40 mTorr (i.e., 5.33 Pa). The RF power is set to be 800 W.

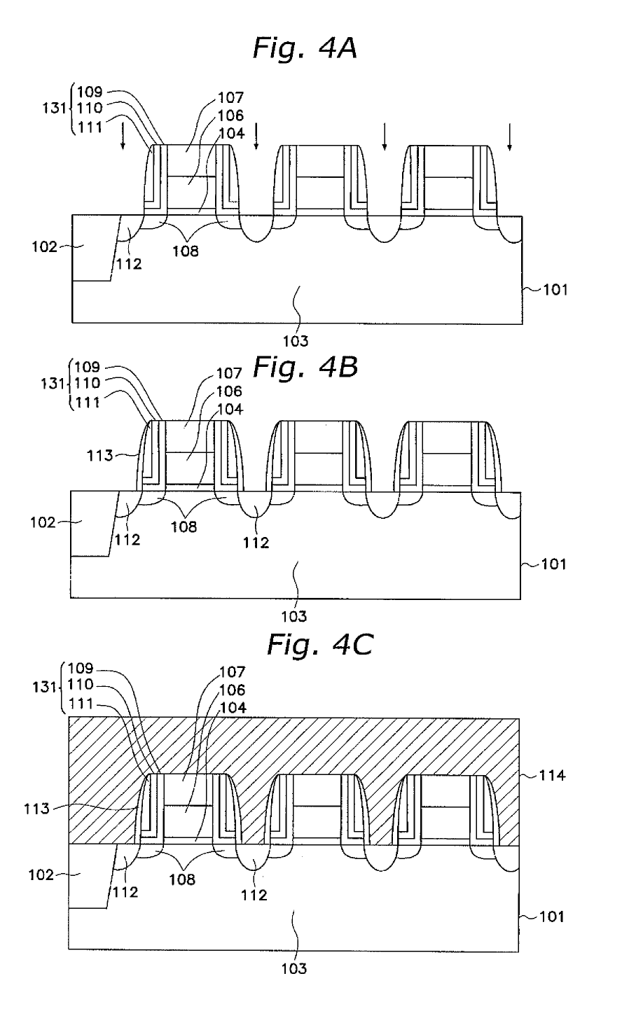

In a step shown in FIG. 4A, firstly, an oxide film functioning as a mask (not shown in the figure) with a thickness of approximately 10 nm, for instance, is formed by means of thermal oxidation or the CVD method so that it covers the exposed portions of the semiconductor substrate 101. Next, ion implantation is performed with respect to portions of the surface of the semiconductor substrate 101 that are located on both sides of the sidewalls 131 through the oxide film functioning as a mask for the purpose of forming a N⁺ diffusion layer. In the ion implantation, arsenic (As) is implanted under conditions in which the acceleration energy is 50 keV and the dose amount is 1×10¹⁵ cm⁻². Then, thermal treatment is performed with respect to the semiconductor substrate 101. Thus, the implanted ions are diffused, and an N⁺ diffusion layer 112 is formed. Each portion of the N⁺ diffusion layer 112 is formed in a smaller shape than the openings in the gate pattern 130 shown in FIG. 1. The difference corresponds to the size of the sidewall 130. Then, the oxide film functioning as a mask is removed.

In a step shown in FIG. 4B, a silicon oxide film with a thickness of 10 to 20 nm, for instance, is formed on the surface of the semiconductor substrate 101. Then, the silicon oxide film is etched back so that the surface of the semiconductor substrate 101 is exposed. Thus, sidewalls 113 are formed. The silicon oxide film is formed by depositing NSG by means of the CVD method, for instance. The conditions of the CVD method are set as follows. The gas flow rate of TEOS (Si(OC₂H₆)₄) is set to be 150 sccm. The chamber pressure is set to be 0.3 Torr (i.e., 40 Pa). At this time, the area of the exposed portions of the semiconductor substrate 101 will be smaller than that of the openings in the gate pattern 130 shown in FIG. 1. In other words, the area of the exposed portions of the semiconductor substrate 101 will be much smaller than that of the exposed portions shown in FIG. 3C. The difference corresponds to the thickness of the sidewall 113. The silicon oxide film is etched back by means of dry etching, for instance. The dry etching conditions are set as follows. For example, the gas flow rate of CHF₃ and CO are set to be 30 and 170 sccm, respectively. The chamber pressure is set to be 40 mTorr (i.e., 5.33 Pa). The RF power is set to be 800 W. Note that in a following step, the sidewall 113 electrically isolates the sidewall 131 and a buried conductive film 114 from each other. More specifically, the sidewall 113 serves to isolate the buried conductive film 114 from the charge storage film 110.

In a step shown in FIG. 4C, firstly, the buried conductive film 114 with the initial thickness of 300 nm is formed on the surface of the silicon substrate 101. The buried conductive film 114 is formed so that it covers the surfaces of the silicon nitride film 107, the sidewall 131, the sidewall 113, and the semiconductor substrate 101. At this time, the buried conductive film 114 fills spaces formed between adjacent pairs of the sidewall 131 and the sidewall 113. In other words, the buried conductive film 114 covers the exposed portions of the N⁺ diffusion layer 112. The buried conductive film 114 is formed by means of the CVD method, for instance. The conditions of the CVD method are set as follows. For example, the gas flow rates of WF₆, SiH₄, H₂, Ar, N₂ are set to be 22, 10, 400, 250, and 350 sccm, respectively. The chamber pressure is set to be 500 Pa.

Note that the initial thickness of the buried conductive film 114 is set to be at least 250 nm or greater, considering the flatness thereof. The reason for this is as follows. That is, the etching amount will vary with the increase of the etching amount in the following steps. Accordingly, there is a possibility that the thickness of the ultimate remaining film will greatly vary. Because of this, considering variation resulting in forming a film and in performing etching, the initial thickness of the buried conductive film 114 is set to be 300 nm, for instance.

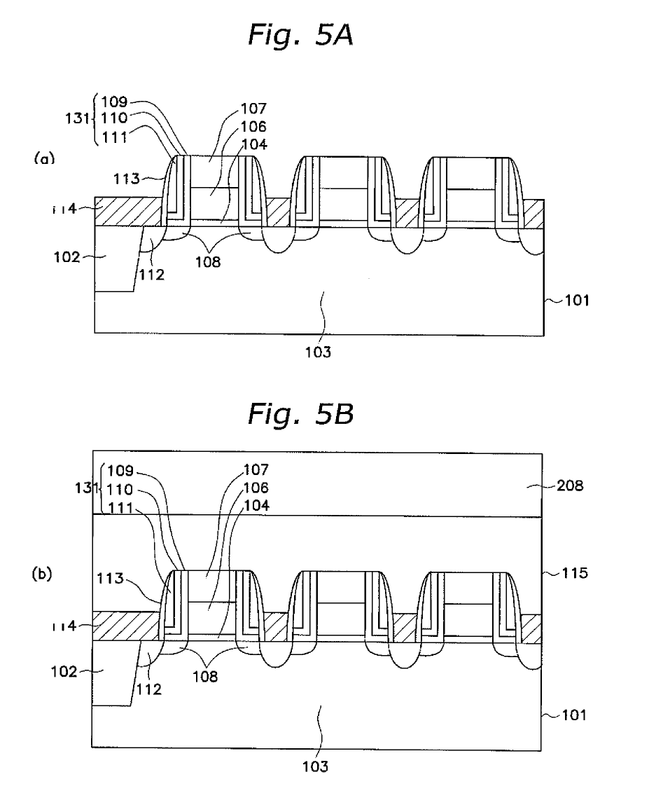

In a step shown in FIG. 5A, firstly, the buried conductive film 114 shown in FIG. 4C is etched back so that the thickness thereof is decreased to 50 to 100 nm. Thus, the buried conductive film 114 shown in FIG. 5A is formed. The buried conductive film 114 is etched back by means of dry etching, for instance. The dry etching conditions are set as follows. For example, the gas flow rates of Cl₂, O₂, CF₄ are set to be 20, 40, and 80 sccm, respectively. The chamber pressure is set to be 5 mTorr (i.e., 0.667 Pa). The RF powers of upper and lower portions are set to be 220 and 75 W, respectively.

The thickness of the buried conductive film 114 is herein explained.

Here, the thicknesses of the gate insulation film 104, the polysilicon film 106, and the silicon nitride film 107 are formed to be 10, 100, and 150 nm, respectively.

Because of this, the sum of the thicknesses of the gate insulation film 104, the polysilicon film 106, and the silicon nitride film 107 is 260 nm. At this time, the heights of the pairs of the sidewall 131 and the sidewall 113 are approximately the same as each other. Note that the thickness of the buried conductive film 114 is 50 to 100 nm as described above. The thickness f the buried conductive film 114 is formed to be half or less of the thickness of a multi-layer laminated film comprised of the gate insulation film 104, the polysilicon film 106, and the silicon nitride film 107.

In a conventional configuration, no buried conductive film is formed, and a CoSi film is formed on a wiring in an N⁺ diffusion layer. Therefore, sheet resistance Rs is set to be 10Ω. Then, the width of the cell slit (i.e., width of the CoSi film) is set to be 0.14 μm. Cell pitch (i.e., length of the CoSi film) is set to be 51.2 μm (i.e., 0.4 μm×the number of cells 128). Accordingly, the resistance R of the CoSi film functioning as a bit line is set to be 3657 Ω (i.e., R=10Ω×51.2 μm/0.14 μm). Here, if electric current (I) flows in writing is set to be 200 μA, decreased voltage (RI) is set to be 0.73 V. If voltage varies 0.5 V or greater, there is a possibility that writing properties will deteriorate. Because of this, the support of a metal wiring is required in an upper layer such as 1M. Specifically, the support is required to be formed along the CoSi film, and thus contacts between the metal wiring and the CoSi film are required to be formed in a plurality of positions.

On the other hand, in the configuration of the present embodiment, if the thickness of the buried conductive film 114 is set to be 50 nm, sheet resistance Rs of the tungsten film is set to be 3 Ω. At this time, if the resistance R of the buried conductive film 114 functioning as a bit line is calculated under the same conditions as that used in the above described conventional configuration, R is set to be 1097 Ω. If electric current (I) that flows in writing is set to be 200 μA, the decreased voltage (RI) is set to be 0.22 V. This is a level in which no support of the metal wiring in an upper layer is necessary. Therefore, the thickness of the buried conductive film 114 is preferably formed to be 50 nm or greater.

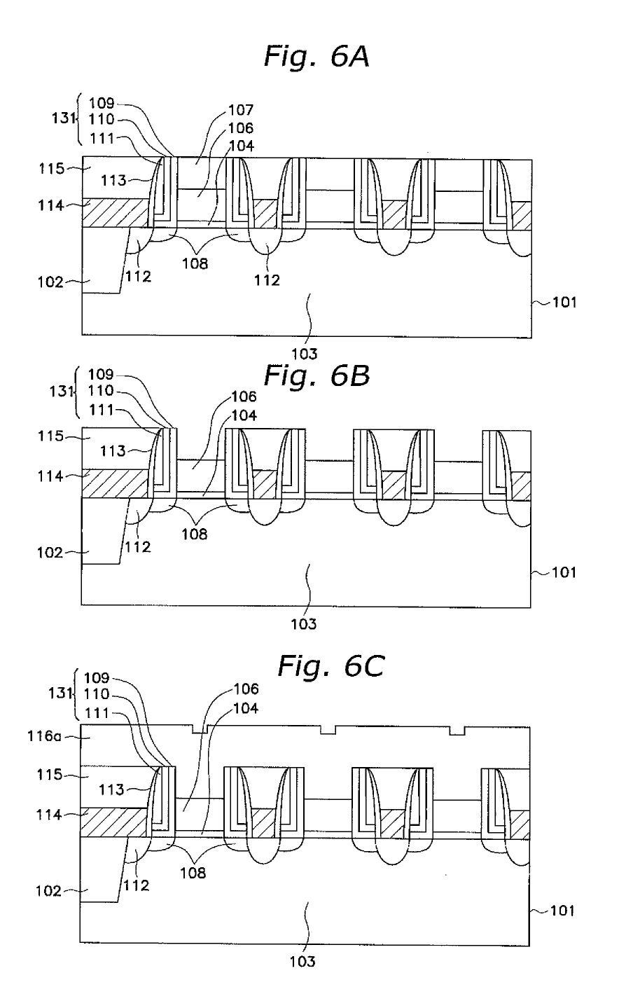

Note that as to the resistance R of the buried conductive film 114 functioning as a bit line, the smaller the better. Because of this, as to the thickness of the buried conductive film 114, the thicker the better. However, in the following step shown in FIG. 6A, a buried insulation film 115 is formed on the buried conductive film 114 so that the height thereof corresponds to the vertical level of the upper surface of the silicon nitride film 107. Then, the buried conductive film 114 and a word line 116 are electrically isolated from each other by means of the thickness of the buried insulation film 115. Because of this, if the thickness of the buried conductive film 114 is formed to be much larger, that of the buried insulation film 115 will be formed to be smaller. As a result, distance between the buried conductive film 114 and the word line 116 will be smaller. Accordingly, there is a possibility that leakage current generates between the buried conductive film 114 and the word line 116.

Thus, considering the electric isolation between the buried conductive film 114 and the word line 116, the thickness of the buried insulation film 115 is required to be formed to be 50 nm or greater as with the thickness of the silicon oxide film 111 of the sidewall 131. Accordingly, the thickness of the buried conductive film 114 is required to be formed to be 210 nm or less (i.e., 260 nm (the vertical level of the upper surface of the silicon nitride film 107 from the surface of the semiconductor substrate 101)—50 nm (the thickness of the buried insulation film 115)).

In addition, when etch back is performed in steps shown in FIGS. 3C and 4B, there is a possibility that the silicon nitride film 107 will be etched and the thickness thereof will be reduced. Furthermore, in the CMP for polishing the silicon oxide film with use of the silicon nitride film 107 as a stopper, there is also a possibility that the silicon nitride film 107 will be polished and the thickness thereof will be reduced. Therefore, it is thought that the thickness of the silicon nitride film 107 will be 80 to 100 nm after the CMP because 50 to 70 nm of its thickness will be removed. Therefore, considering the thickness of the silicon nitride film 107 to be removed (i.e., 50 to 70 nm), the vertical level of the upper surface of the silicon nitride film 107 from the surface of the semiconductor substrate 101 is set to be 190 to 210 nm. Here, considering the thickness of the buried insulation film 115 that is necessary for isolation (i.e., 50 nm), the thickness of the buried conductive film 114 is set to be 120 to 140 nm. Accordingly, considering other factors such as variation of the thickness of the buried insulation film 115, the thickness of the buried conductive film 114 is preferably set to be 100 nm or less.

As a result, in the present embodiment, the thickness of the buried conductive film 114 is preferably set to be 50 nm or greater and 100 nm or less.

Next, the subsequent steps after the step shown in FIG. 5A in which the buried conductive film 114 is formed are hereinafter explained.

In a step shown in FIG. 5B, a buried insulation film 115 that is comprised of a silicon oxide film is formed on the surface of the semiconductor substrate 101 shown in FIG. 5A. The buried insulation film 115 covers the gates, pairs of the sidewall 131 and the sidewall 113, and the buried conductive film 114 as shown in FIG. 5B. At this time, the silicon nitride film 105 is covered with the peripheral circuit region 1002. The buried insulation film 115 is formed to fill spaces formed between pairs of the sidewall 131 and the sidewall 113 so that it covers the buried conductive film 114.

The buried insulation film 115 is formed by depositing NSG by means of the CVD method, for instance. The conditions of the CVD method are set as follows. The gas flow rate of TEOS (Si(OC₂H₆)₄) is set to be 150 sccm. The chamber pressure is set to be 0.3 Torr (i.e., 40 Pa).

Then, portions of the buried insulation film 115 on the silicon nitride film 105 in the peripheral circuit region 1002 are removed. Next, portions of the buried insulation film 115 in the memory cell region 1001 are left unremoved. Portions of the buried insulation film 115 are removed by means of dry etching, for instance. The dry etching conditions are set as follows. For example, the gas flow rate of CHF₃ and CO are set to be 30 and 170 sccm, respectively. The chamber pressure is set to be 40 mTorr (i.e., 5.33 Pa). The RF power is set to be 800 W.

Furthermore, subsequent steps of the manufacturing method of the semiconductor device 1000 will be hereinafter explained. Here, a transistor will be formed in the peripheral circuit region 1002 while the memory cell region 1001 is covered with the buried insulation film 115.

In a step shown in FIG. 9B, the silicon nitride film 105 is removed in the peripheral circuit region 1002, and thus the gate insulation film 104 is exposed. The buried insulation film 115 is removed by means of dry etching, for instance. The dry etching conditions are set as follows. For example, the gas flow rate of CF₄, CH₂F₂, and He are set to be 45, 30, and 100 sccm, respectively. The chamber pressure is set to be 10 mTorr (i.e., 1.33 Pa). The RF powers of upper and lower portions are set to be 900 and 80 W, respectively.

In a step shown in FIG. 9C, a polysilicon film 201 with a thickness of 50 nm, a tungsten silicide film (WSi film) 202 with a thickness of 50 nm, a silicon oxide film (above-gate insulation film) 203 with a thickness of 30 nm, and a silicon nitride film 204 with a thickness of 120 nm, are sequentially formed on the gate insulation film 104, for instance. The polysilicon film 201 is formed by means of the CVD method, for instance. The conditions of the CVD method are set as follows. For example, the gas flow rate of SiH₄ is set to be 250 sccm. The chamber pressure is set to be 0.20 Torr (i.e., 26.7 Pa). The WSi film 202 is formed by means of the sputtering method, for instance. The conditions of the sputtering method are set as follows. For example, WSi is set as a target. The gas flow rate of atmosphere gas Ar is set to be 33 sccm. The chamber pressure is set to be 0.56 Pa. DC power is set to be 2 kW. The silicon oxide film 203 is formed by depositing NSG by means of the CVD method, for instance. The conditions of the CVD method are set as follows. The gas flow rate of TEOS (Si(OC₂H₆)₄) is set to be 150 sccm. The chamber pressure is set to be 0.3 Torr (i.e., 40 Pa). The silicon nitride film 204 is formed by means of the CVD method, for instance. The conditions of the CVD method are set as follows. For example, the gas flow rates of NH₃ and SiH₂Cl₂ are set to be 1000 and 100 sccm, respectively. The chamber pressure is set to be 0.35 Torr (i.e., 46.7 Pa). The silicon nitride film 204 functions as a stopper when after-mentioned CMP is performed.

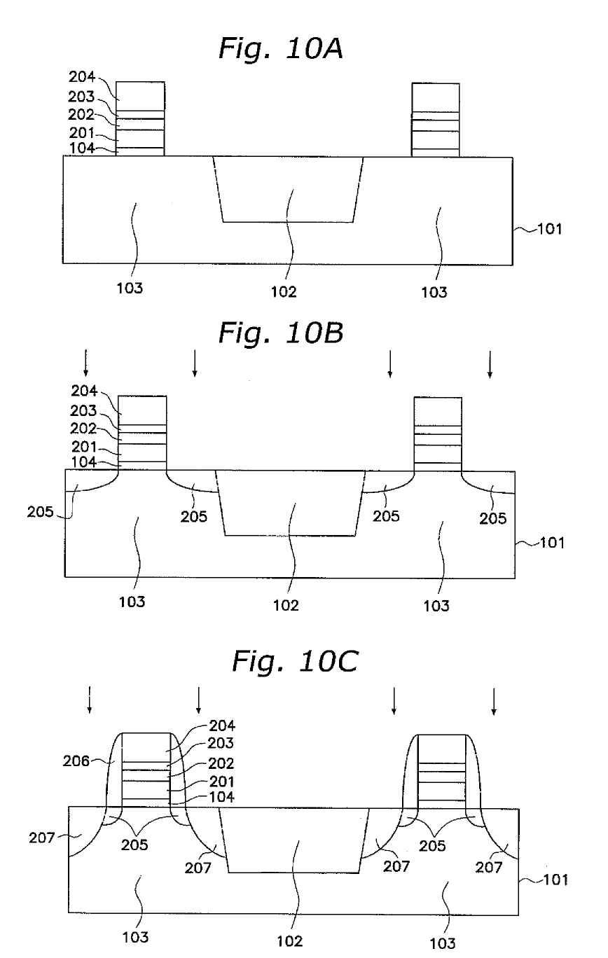

Next, in a step shown in FIG. 10A, a region of a peripheral circuit transistor Tr2 that will be a gate is covered with a resist. Then, the gate insulation film 104, the polysilicon film 201, the WSi film 202, the above-gate insulation film 203, and the silicon nitride film 204 are patterned in a gate shape with use of the resist as a mask. Because of this, both sides of the gates are exposed.

The silicon nitride film 204 and the above-gate insulation film (silicon oxide film) 203 are removed by means of dry etching, for instance. The dry etching can be performed under the following conditions. For example, the gas flow rates of CF₄, CH₂F₂, and He are set to be 45, 30, and 100 sccm, respectively. The chamber pressure is set to be 10 mTorr (i.e., 1.33 Pa). The RF powers of upper and lower portions are set to be 900 and 80 W, respectively. The WSi film 202 is removed by means of dry etching, for instance. The dry etching can be performed under the following conditions. For example, the gas flow rates of Cl₂ and O₂ are set to be 20 and 2 sccm, respectively. The chamber pressure is set to be 3 mTorr (i.e., 0.4 Pa). The RF powers of upper and lower portions are set to be 220 and 120 W, respectively. The polysilicon film 201 is removed by means of dry etching, for instance. The dry etching can be performed under the following conditions. For example, the gas flow rates of HBr and O₂ are set to be 100 and 3 sccm, respectively. The chamber pressure is set to be 5 mTorr (i.e., 0.667 Pa). The RF powers of upper and lower portions are set to be 350 and 30 W, respectively.

In a step shown in FIG. 10B, firstly, an oxide film functioning as a mask (not shown in the figure) with a thickness of approximately 10 nm, for instance, is formed by means of thermal oxidation or the CVD method so that it covers the exposed portions of the semiconductor substrate 101 shown in FIG. 10A. Then, an ion implantation is performed with respect to portions of the surface of the semiconductor substrate 101 located on both sides of the gates through the oxide film functioning as a mask for the purpose of forming LDDs. In the ion implantation, phosphorus (P) is implanted under conditions in which the acceleration energy is 30 keV and the dose amount is 2×10¹³ cm⁻². Then, thermal treatment is performed with respect to the semiconductor substrate 101. Thus, the implanted ions are diffused, and LDDs 205 are formed.

In a step shown in FIG. 10C, a silicon oxide film is formed on the surface of the semiconductor substrate 101, and then it is etched back so that the surface of the semiconductor device 101 is exposed. Next, sidewalls 206 are formed on both sides of the gates as shown in FIG. 10C. The silicon oxide film is formed by depositing NSG by means of the CVD method, for instance. The CVD method can be performed under the following conditions. The gas flow rate of TEOS (Si(OC₂H₆)₄) is set to be 150 sccm. The chamber pressure is set to be 0.3 Torr (i.e., 40 Pa). The silicon oxide film is etched back by means of dry etching, for instance. The dry etching can be performed under the following conditions. For example, the gas flow rates of CHF₃ and CO are set to be 30 and 170 sccm, respectively. The chamber pressure is set to be 40 mTorr (i.e., 5.33 Pa). The RF power is set to be 800 W.

Next, an oxide film functioning as a mask (not shown in the figure) with a thickness of approximately 10 nm is formed by means of thermal oxidation or the CVD method so that it covers the exposed portions of the semiconductor substrate 101. Then, ion implantation is performed with respect to portions of the surface of the semiconductor substrate 101 located on both sides of the sidewalls 206 shown in FIG. 10C through the oxide film functioning as a mask for the purpose of forming an N⁺ diffusion layer. In the ion implantation, arsenic (As) is implanted under conditions in which the acceleration energy is 50 keV and the dose amount is 1×10¹⁵ cm⁻², for instance. Then, thermal treatment is performed with respect to the semiconductor substrate 101, and the implanted ions are diffused. Thus, an N⁺ diffusion layer 207 is formed as shown in FIG. 10C.

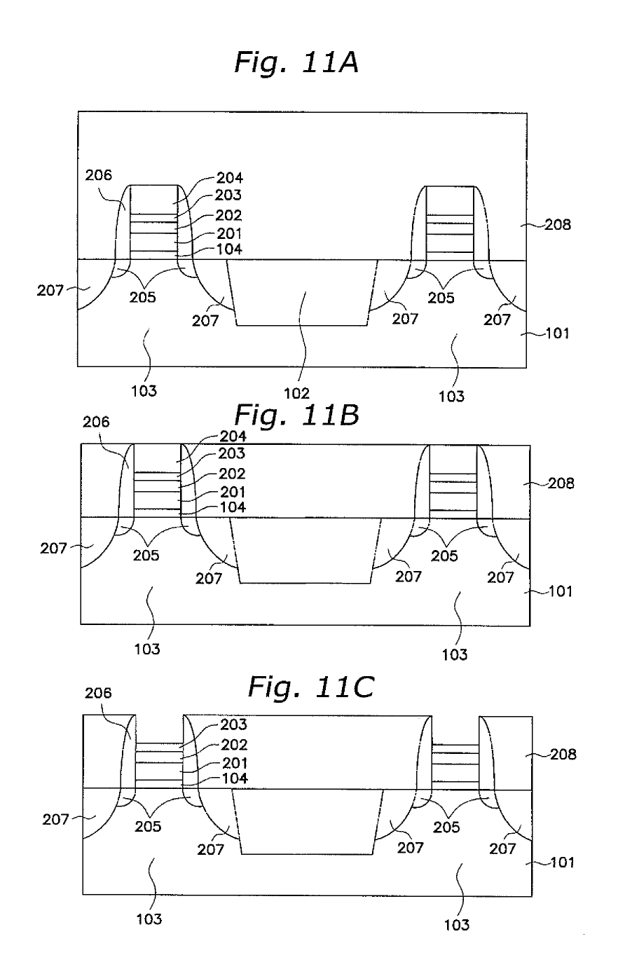

In a step shown in FIG. 11A, a buried insulation film 208 with a thickness of 300 to 400 nm is formed on the surface of the semiconductor substrate 101. The buried insulation film 208 is formed so that it covers the surfaces of the gates, the sidewalls 206, and the semiconductor substrate 101 in the peripheral circuit region 1002. In addition, as shown in FIG. 5B, the buried insulation film 208 is formed to cover the buried insulation film 115. The buried insulation film 208 is formed by depositing NSG by means of the CVD method, for instance. The CVD method can be performed under the following conditions. The gas flow rate of TEOS (Si(OC₂H₆)₄) is set to be 150 sccm. The chamber pressure is set to be 0.3 Torr (i.e., 40 Pa).

Next, steps of forming wirings in the memory cell region 1001 and the peripheral circuit region 1002, for instance, will be hereinafter explained.

In steps shown in FIGS. 5B and 11A, planarization and thickness reduction are performed with respect to the buried insulation films 115 and 208, respectively, by means of CMP. In the CMP, polishing is performed with the silicon nitride film 107 in the memory cell region 1001 and the silicon nitride film 204 in the peripheral circuit region 1002, both of which function as stoppers. Because of this, it is preferable that height of the silicon nitride film 107 in the memory cell region 1001 and that of the silicon nitride film 204 in the peripheral circuit region 1002 are formed to be approximately the same. In the memory cell region 1001, the buried insulation film 115 is polished so that the silicon nitride film 107 shown in FIG. 5B is exposed. Then, as shown in FIG. 6A, the height of the buried insulation film 115 is formed to be approximately the same as that of the silicon nitride film 107.

In the peripheral circuit region 1002, the buried insulation film 208 is polished so that the silicon nitride film 204 shown in FIG. 11A is exposed. Then, as shown in FIG. 11B, height of the buried insulation film 208 is formed to be approximately the same as that of the silicon nitride film 204.

In steps shown in FIGS. 6B and 11C, silicon nitride films 107 and 204 that were used as stoppers for CMP are removed, respectively. As a result, as shown in FIG. 6B, the polysilicon film 106 is exposed in the memory cell region 1001. On the other hand, as shown in FIG. 11C, the above-gate insulation film 203 is exposed in the peripheral circuit region 1002. The silicon nitride films 107 and 204 are removed by means of wet etching using thermal phosphoric acid, for instance.

Next, in a step shown in FIG. 6C, a tungsten film 116a with a thickness of 100 nm is formed on the surface of the semiconductor substrate 101. The tungsten film 116a is formed to cover the polysilicon film 106. The tungsten film 116a is formed to fill spaces inside pairs of the sidewall 131 and the sidewall 113 and cover the polysilicon film 106. The tungsten film 116a is formed by means of the CVD method, for instance. The CVD method can be performed under the following conditions. For example, the gas flow rates of WF₆, SiH₄, H₂, Ar, and N₂ are set to be 22, 10, 400, 250, and 350 sccm, respectively. The chamber pressure is set to be 500 Pa.

In a step shown in FIG. 7A, after a silicon oxide film with a thickness of 100 nm is formed on the tungsten film 116a shown in FIG. 6C, the silicon oxide film is patterned in a shape of the word line 116 shown in FIG. 1. Thus, a hard mask 117 is formed. The silicon oxide film is formed by depositing NSG by means of the CVD method, for instance. The CVD method can be performed under the following conditions. The gas flow rate of TEOS (Si(OC₂H₆)₄) is set to be 150 sccm. The chamber pressure is set to be 0.3 Torr (i.e., 40 Pa). The silicon oxide film is etched by means of dry etching, for instance. The dry etching can be performed under the following conditions. For example, the gas flow rates of CF₄, CH₂F₂, and He are set to be 45, 30, and 100 sccm, respectively. The chamber pressure is set to be 10 mTorr (i.e., 1.33 Pa). The RF powers of upper and lower portions are set to be 900 and 80 W, respectively.

In a step shown in FIG. 8A, firstly, the tungsten film 116a is patterned in a shape of the word line 116 shown in FIG. 1 with use of the hard mask 117 as a mask. Thus, the word line 116 shown in FIGS. 1 and 7A is formed. As a result, as shown in a C-C cross-section of FIG. 8A, portions of the tungsten film 116a that are not covered with the hard mask 117 are removed, and thus the polysilicon film 106 is exposed. The tungsten film 116a is etched by means of dry etching, for instance. The dry etching can be performed under the following conditions. For example, the gas flow rates of Cl₂, O₂, and CF₄ are set to be 20, 40, and 80 sccm, respectively. The chamber pressure is set to be 5 mTorr (i.e., 0.667 Pa). The RF powers of upper and lower portions are set to be 220 and 75 W, respectively.

In a step shown in FIG. 8B, the hard mask 117 is further used as a mask, and the polysilicon film 106 shown in FIG. 8A is removed. At this time, as shown in FIG. 11C, the polysilicon film 201 and the WSi film 202 are covered with the above-gate insulation film (silicon oxide film) 203 in the peripheral circuit region 1002. Because of this, the polysilicon film 201 and the WSi film 202 are not removed. The polysilicon film 106 is etched by means of dry etching, for instance. The dry etching can be performed under the following conditions. For example, the gas flow rates of HBr and O₂ are set to be 100 and 3 sccm, respectively. The chamber pressure is set to be 5 mTorr (i.e., 0.667 Pa). The RF powers of upper and lower portions are set to be 350 and 30 W, respectively.

In a step shown in FIG. 8C, an intermediate insulation film 118 is formed on the surface of the semiconductor substrate 101. As shown in FIG. 7B, in the region of the word line 116 in the memory cell region 1001, the intermediate insulation film 118 is formed to cover the hard mask 117. On the other hand, as shown in FIG. 8C, in regions other than the region of the word line 116, the intermediate insulation film 118 is formed to fill spaces between pairs of the sidewall 113 and the sidewall 131 so that it covers the gate insulation film 104. In addition, the intermediate insulation film 118 is formed to cover the buried insulation film 115.

Furthermore, as shown in FIG. 12, the intermediate insulation film 118 is filled in spaces inside the sidewalls 206 and covers the above-gate insulation film 203, and at the same time as this, covers the buried insulation film 208. The intermediate insulation film 118 is formed by depositing NSG by means of the CVD method, for instance. The dry etching can be performed under the following conditions. For example, the gas flow rates of SH₄, O₂, and Ar are set to be 90, 155, and 150 sccm, respectively. The chamber pressure is set to be 8 mTorr (i.e., 1067 Pa). The RF powers of upper and lower portions are set to be 1800 and 3500 W, respectively.

Next, methods for forming contacts 120 and 221 shown in FIG. 1 are hereinafter explained. Note that a contact hole 120a and the contact 120 are shown with a dashed-line in FIG. 8C. First, a resist pattern for forming the contacts 120 and 221 shown in FIG. 1 is formed on the intermediate insulation film 118. Then, the intermediate insulation film 118 and the buried insulation film 115 shown in FIG. 8C are processed in the memory cell region 1001 with use of the resist pattern as a mask. Thus, a contact hole 120a to expose the buried conductive film 114 is formed.

In addition, as shown in FIG. 12, the intermediate insulation film 118 and the buried insulation film 208 are processed in the peripheral circuit region 1002. Thus, a contact hole 221a to expose portions of the N⁺ diffusion layer 207 is formed.

Portions of the intermediate insulation film 118 and the buried insulation films 115 and 207 are removed by means of dry etching, for instance. The dry etching can be performed under the following conditions. For example, the gas flow rates of CF₄, CH₂F₂, and He are set to be 45, 30, and 100 sccm, respectively. The chamber pressure is set to be 10 mTorr (i.e., 1.33 Pa). The RF powers of upper and lower portions are set to be 900 and 80 W, respectively.

A conductive film made of aluminum is formed on the intermediate insulation film 118. In addition, a conductive film is filled in the contact holes 120a and 221a. Thus, the contacts 120 that are coupled to the buried conductive film 114 and the contacts 221 that are coupled to the N⁺ diffusion layer 207 are formed. Then, the conductive film is patterned in a predetermined wiring shape. Thus, 1M wiring 121 is formed.

As described above, according to the present embodiment, the buried conductive film 114 is filled in the spaces between pairs of the sidewall 131 and the sidewall 113, and thus it is formed on the N⁺ diffusion layer 112 so that it is disposed along the N⁺ diffusion layer 112. Because of this, the resistance value of the wiring (bit line) comprised of the buried conductive film 114 and the N⁺ diffusion layer 112 can be reduced. In addition, because of this, it will be easier to prevent the semiconductor device 1000 from being formed in a large size. Note that the buried conductive film 114 is only filled in the spaces between pairs of the sidewall 131 and the sidewall 113. Therefore, with the buried conductive film 114, the semiconductor device 1000 has a small chance of being formed in a large size.

In this regard, the configuration of the semiconductor device in accordance with the present embodiment is different from that of the semiconductor device in which contacts are formed between a metal wiring and a diffusion layer in a plurality of positions and a region for forming a contact is required to be reserved.

In addition, the buried conductive film 114 is filled in the spaces formed between pairs of the sidewall 131 and the sidewall 113. Therefore, it will be easier to adjust thickness of the buried conductive film 114. Because of this, the resistance value of the wiring comprised of the buried conductive film 114 and the N⁺ diffusion layer 112 can be easily adjusted.

In addition, the memory cell transistor Tr1 and the peripheral circuit transistor Tr2 are separately formed. Therefore, it is possible to prevent the hot carrier resistance of the peripheral circuit transistor Tr2 from being reduced, which is caused by formation of the charge storage film in the gate of the peripheral circuit transistor Tr2. Furthermore, it is possible to prevent a silicide film from being formed in the gate of the memory cell transistor Tr1.

Furthermore, a silicide film is formed in the gate of the memory cell transistor Tr1. Therefore, it is not necessary to perform etching of a multi-layer film, and thus an etching step will be simplified. In addition, the number of layers comprising a gate electrode is relatively small. Therefore, it is possible to reduce the degree of a taper formed in an etching step of a gate electrode, in other words, the shape of the gate electrode in which width of an upper layer is smaller than that of a lower layer. Therefore, the lateral sides of the gate electrode will be formed to be approximately vertical, and thus etching will be easily performed.

### Second Embodiment

A second embodiment of the present invention will now be described by focusing the differences with the above described first embodiment of the present invention. In view of the similarity between the first and second embodiments, the parts of the second embodiment that are identical to the parts of the first embodiment will be given the same reference numerals as parts of the first embodiment. Moreover, the descriptions of the parts of the second embodiment that are identical to the parts of the first embodiment may be omitted for the sake of brevity.

A semiconductor device 1000 in accordance with the present embodiment is different from that in accordance with the first embodiment in that a gate electrode comprised of a polysilicon film 201 and a WSi film 202 is used instead of using the gate electrode comprised of the polysilicon 106 shown in FIG. 1. Other configurations of the semiconductor device 1000 in accordance with the present embodiment are the same as those of the semiconductor device 1000 in accordance with the first embodiment.

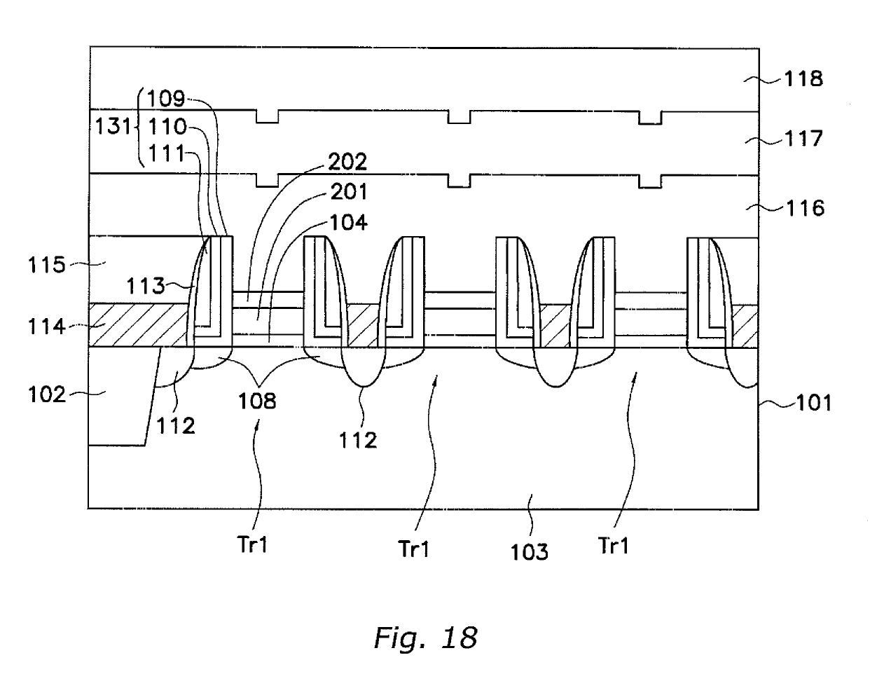

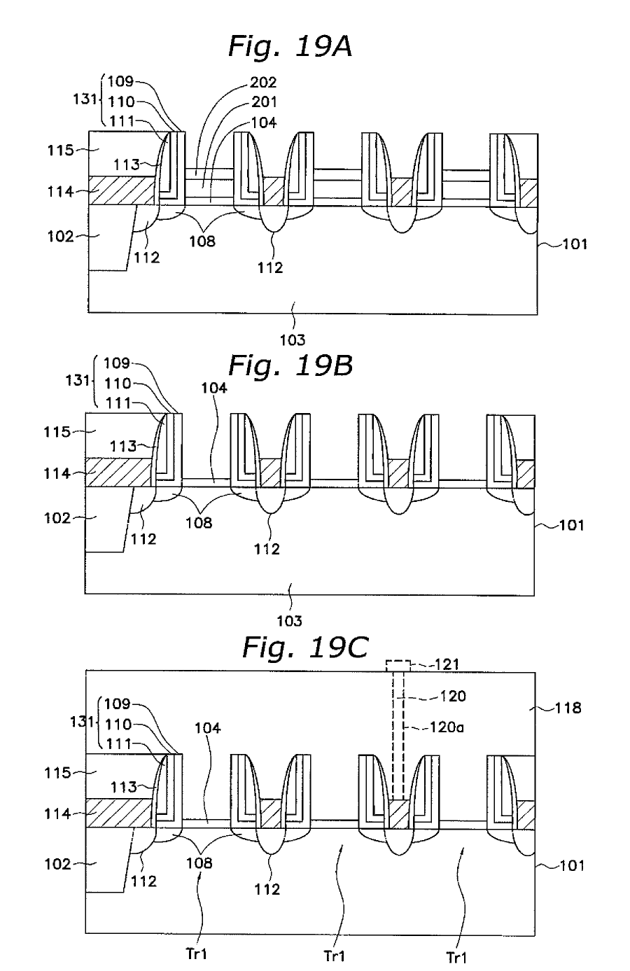

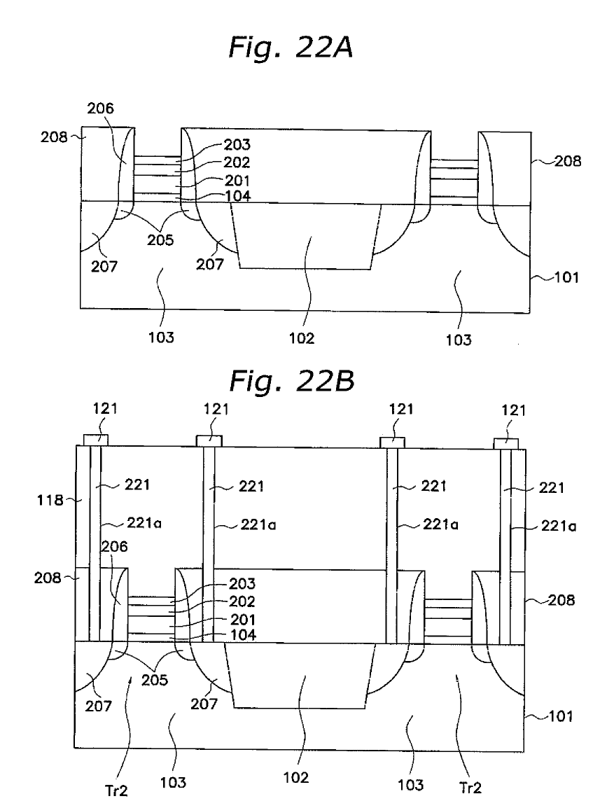

FIG. 18 is a diagram showing a cross-section of FIG. 1 in accordance with the present embodiment indicated by Arrow A-A. FIGS. 19A to 19C are diagrams showing a cross-section of FIG. 1 in accordance with the present embodiment indicated by Arrow C-C. FIGS. 22A and 22B are diagrams showing a cross-section of FIG. 1 in accordance with the present embodiment indicated by Arrow B-B.

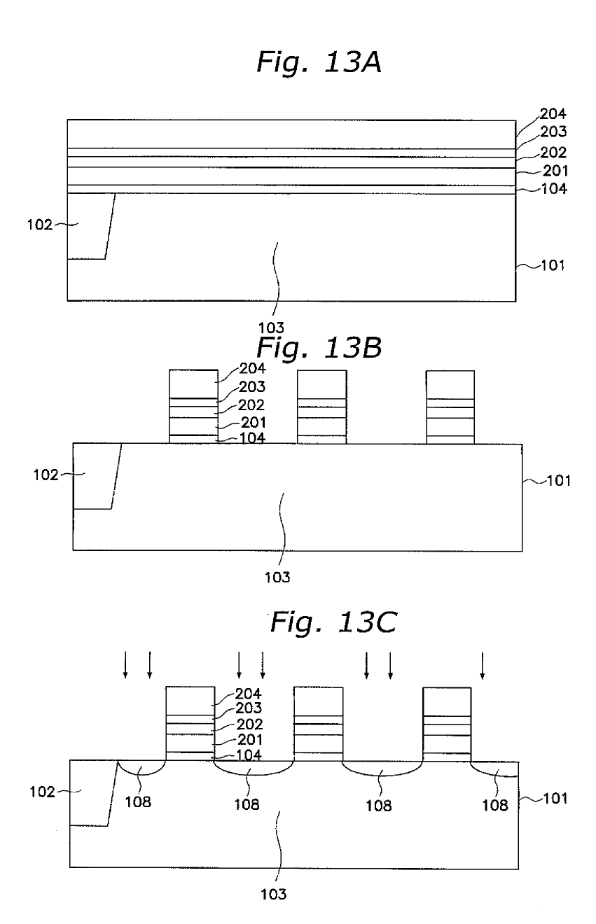

In FIGS. 13A to 13C, 18 and 22B, the configuration of the semiconductor device 1000 in accordance with the present embodiment is the same as that of the semiconductor device 1000 in accordance with the first embodiment except that the gate structures of the memory cell transistor Tr1 in both embodiments are different from each other. Note that in the following explanation of the second embodiment, components/members in accordance with the second embodiment, which correspond to those in accordance with the first embodiment, are given the same numerals used in the first embodiment, and explanations of these components/members are thereinafter omitted.

A gate of a memory cell transistor Tr1 in accordance with the present embodiment shown in FIG. 18 is comprised of a gate insulation film 104, a polysilicon film 201, and a tungsten silicide film (WSi film) 202, and is different from the gate of the memory cell transistor Tr1, which is comprised of the gate insulation film 104 and the polysilicon film 106, in accordance with the first embodiment shown in FIG. 7B. In the first embodiment, the gate electrode is only comprised of the polysilicon film 106, but the gate electrode in accordance with the present embodiment is comprised of the polysilicon film 201 and the WSi film 202.

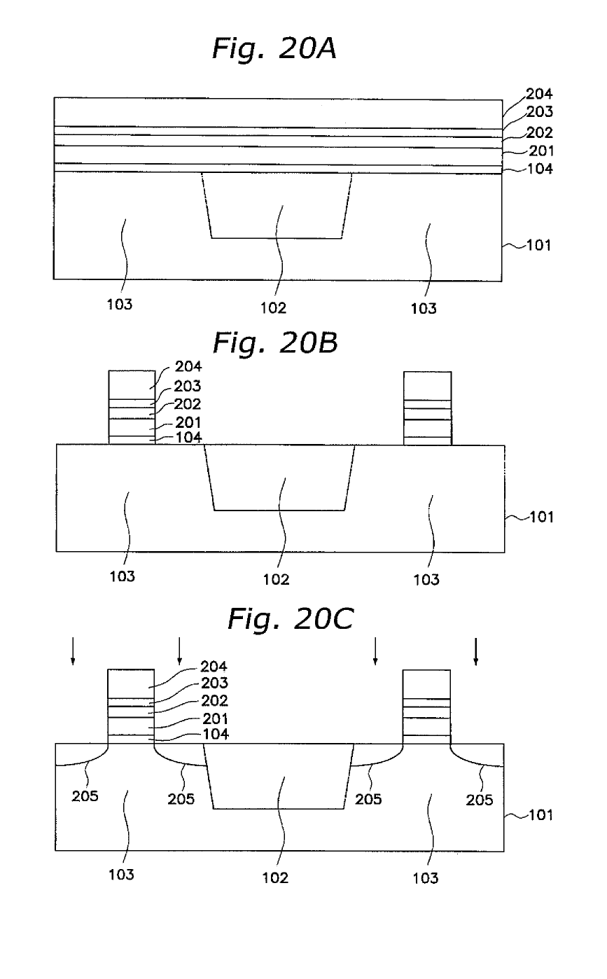

Next, a manufacturing method of a semiconductor device 1000 in accordance with the present embodiment will be hereinafter explained. FIGS. 13A to 13C, 14A to 14C, 15A to 15C, 16A to 16C, 17A and 17B, 18, 19A to 19C, 20A to 20C, 21A to 21C, and 22A and 22B are process diagrams showing a manufacturing method of the semiconductor device 1000 in accordance with the present embodiment. Note that FIGS. 13A to 13C, 14A to 14C, 15A to 15C, 16A to 16C, 17A and 17B, and 18 are process diagrams of the semiconductor device 1000 viewed from a cross-section A-A thereof shown in FIG. 1. FIGS. 19A to 19C are process diagrams thereof viewed from a cross-section C-C thereof shown in FIG. 1. FIGS. 20A to 20C, 21A to 21C, and 22A and 22B are process diagrams thereof viewed from a cross-section B-B thereof shown in FIG. 1.

In a step shown in FIGS. 13A and 20A, a semiconductor substrate 101 made of silicon, for instance, is prepared as with the step shown in FIGS. 2A and 9. Then, a gate insulation film 104 with a thickness of 10 nm, a polysilicon film 201 with a thickness of 50 nm, a tungsten silicide film (WSi film) 202 with a thickness of 50 nm, a silicon oxide film (above-gate insulation film) 203 with a thickness of 30 nm, and a silicon nitride film 204 with a thickness of 120 nm, are sequentially formed on the surface of the semiconductor substrate 101, for instance.

The polysilicon film 201 is formed by means of the CVD method, for instance. The conditions of the CVD method are set as follows. For example, the gas flow rate of SiH₄ is set to be 250 sccm. The chamber pressure is set to be 0.20 Torr (i.e., 26.7 Pa). The WSi film 202 is formed by means of the sputtering method, for instance. The conditions of the sputtering method are set as follows. For example, Wsi is set as a target. The gas flow rate of atmosphere gas Ar is set to be 33 sccm. The chamber pressure is set to be 0.56 Pa. DC power or RF power is set to be 2 kW. The silicon oxide film 203 is formed by depositing NSG by means of the CVD method, for instance. The conditions of the CVD method are set as follows. The gas flow rate of TEOS (Si(OC₂H₆)₄) is set to be 150 sccm. The chamber pressure is set to be 0.3 Torr (i.e., 40 Pa). The silicon nitride film is formed by means of the CVD method as with formation of the silicon nitride film 107 in accordance with the first embodiment. The silicon nitride film 204 functions as a stopper when after-mentioned CMP is performed.

In a step shown in FIG. 13B, a resist pattern is formed that covers a region to be a gate of the cell transistor Tr1 in a memory cell region 1001 and the whole region of a peripheral circuit region 1002. The region to be gates in the memory cell region 1001 corresponds to a shape of the gate pattern 130 shown in FIG. 1. The silicon nitride film 204, the above-gate insulation film 203, the WSi film 202, the polysilicon film 201, and the gate insulation film 104 are patterned with the use of this resist pattern as a mask. As a result, as shown in FIG. 13B, gates are formed, each of which are comprised of the silicon nitride film 204, the above-gate insulation film 203, the WSi film 202, the polysilicon film 201, and the gate insulation film 104. In addition, portions on both sides of the gates are exposed, and thus portions corresponding to openings in the gate pattern 130 shown in FIG. 1 are exposed.

Portions of the silicon nitride film 204 and those of the above-gate insulation film (silicon oxide film) 203 are removed by means of dry etching under the same condition as that of the dry etching for the silicon nitride film 203 in accordance with the first embodiment, for instance. Portions of the WSi film 202 are removed by means of dry etching, for instance. The dry etching can be performed under the following conditions. For example, the gas flow rates of Cl₂ and O₂ are set to be 20 and 2 sccm, respectively. The chamber pressure is set to be 3 mTorr (i.e., 0.4 Pa). The RF powers of upper and lower portions are set to be 220 and 120 W, respectively. Portions of the polysilicon film 201 are removed by means of dry etching under the same condition as that of the dry etching for the polysilicon film 106 in accordance with the first embodiment, for instance.

In a step shown in FIG. 13C, LDDs 108 are formed by means of the same method as that used in the step shown in FIG. 3A, and then an oxidation film functioning as a mask is removed.

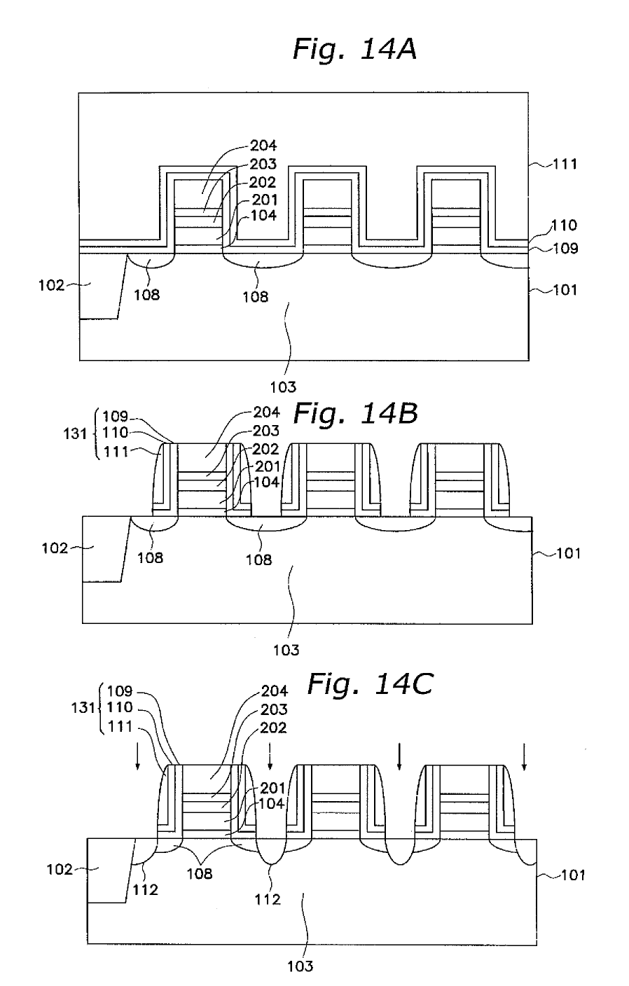

In a step shown in FIG. 14A, a silicon oxide film 109 with a thickness of 10 nm, a silicon nitride film (charge storage film) 110 with a thickness of 8 nm, and a silicon oxide film 111, for instance, are sequentially formed on the surface of the semiconductor substrate 101 by means of the same method as that used in the step shown in FIG. 3B.

In a step shown in FIG. 14B, the silicon oxide film 111, the charge storage film 110, and the silicon oxide film 109 shown in FIG. 14A are etched back by means of dry etching, for instance, so that the surface of the semiconductor substrate 101 is exposed as with etch back of the silicon oxide film 111, the charge storage film 110, and the silicon oxide film 107 shown in FIG. 3C. Then, as shown in FIG. 14B, sidewalls 131, each of which is comprised of the silicon oxide film 109 with a thickness of 10 nm, the charge storage film 110 with a thickness of 8 nm, and the silicon oxide film 111 with a thickness of 50 nm is formed, for instance. At this time, the area of the exposed portions of the semiconductor substrate 101 will be one size smaller than that of the openings in the gate pattern 130 shown in FIG. 1.

In a step shown in FIG. 14C, an N⁺ diffusion layer 112 is formed by means of the same method as that used in the step shown in FIG. 4A, and then an oxide film functioning as a mask is removed.

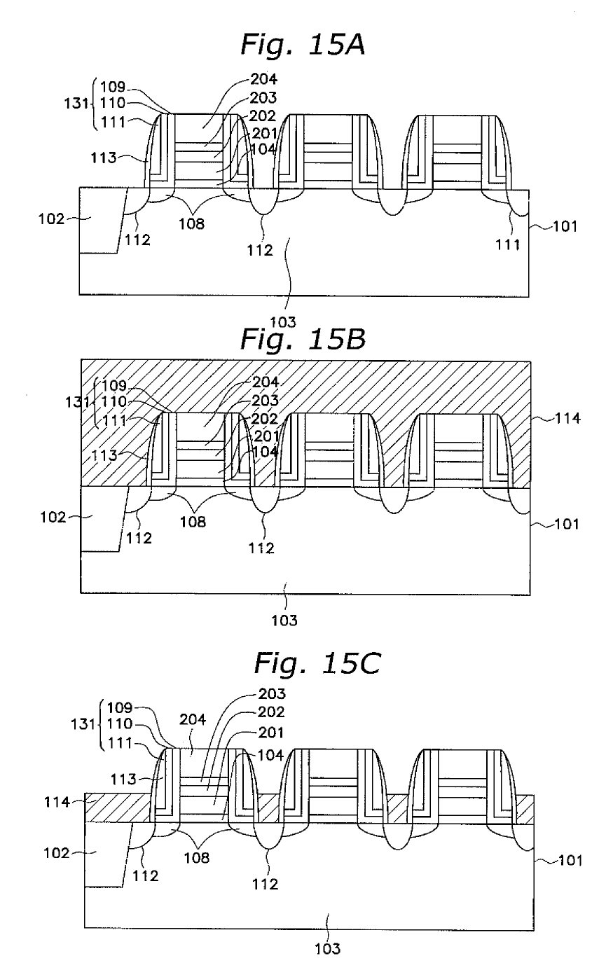

In a step shown in FIG. 15A, a silicon oxide film is formed by means of the same method as that used in the step shown in FIG. 4A, and then a sidewall 113 is formed. The sidewall 113 serves to electrically isolate a buried conductive film 114 and the charge storage film 110 from each other.

In a step shown in FIG. 15B, the buried conductive film 114 with the initial thickness of 300 nm is formed on the surface of the silicon substrate 101 by means of the same method as that used in the step shown in FIG. 4C.

In a step shown in FIG. 15C, the buried conductive film 114 is etched back by means of the same method as that used in the step shown in FIG. 5A so that the buried conductive film 114 with a thickness of 50 to 100 nm is left.

Note that in the present embodiment, the thicknesses of the gate insulation film 104, the polysilicon film 201, the WSi film 202, the above-gate insulation film 203, and the silicon nitride film 204 are formed to be 10, 50, 50, 30, and 120 nm, respectively. Therefore, based on the same reason as that for the first embodiment, the thickness of the buried conductive film 114 is preferably set to be 50 nm or greater and 100 nm or less.

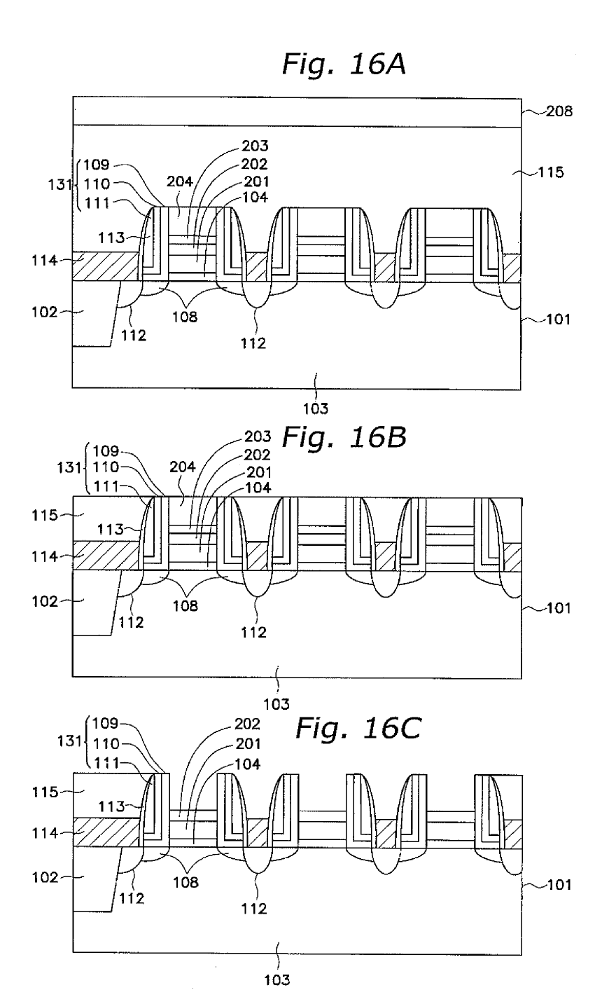

In a step shown in FIG. 16A, a buried insulation film 115 is formed to cover the gates, pairs of the sidewall 131 and the sidewall 113, and the buried conductive film 114 by means of the same method as that used in the step shown in FIG. 5B. In addition, the buried insulation film 115 is formed to cover the silicon nitride film 204 in the peripheral circuit region 1002.

Next, subsequent steps of the manufacturing method of the semiconductor device 1000 will be hereinafter explained. Here, a peripheral circuit transistor Tr will be formed in the peripheral circuit region 1002 while the memory cell region 1001 is covered with the buried insulation film 115.

In a step shown in FIG. 20B, gates comprised of the gate insulation film 104, the polysilicon film 201, the WSi film 202 are formed by means of the same method as that used in the step shown in FIG. 10A.

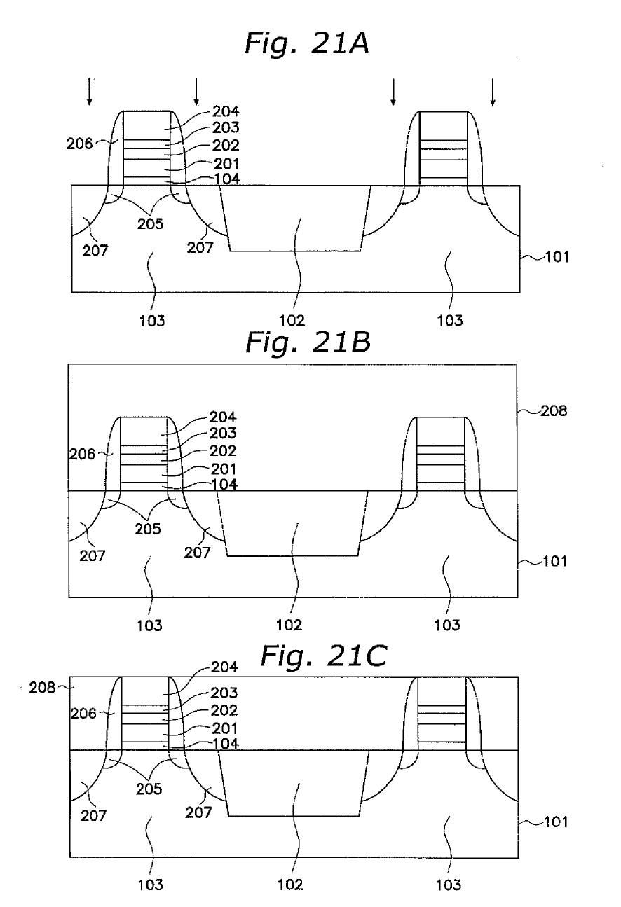

In a step shown in FIG. 20C, LDDs 205 are formed by means of the same method as that used in the step shown in FIG. 10B. In a step shown in FIG. 21B, a buried insulation film 208 is formed to cover the buried insulation film 115 in the memory cell region 1001 by means of the same method as that used in the step shown in FIG. 11A.

In the steps shown in FIGS. 16B and 21C, planarization and thickness reduction are performed with respect to the buried insulation films 115 and 208 shown in FIGS. 16A and 21B by means of CMP. In the CMP, polishing is performed with use of the silicon nitride film 204 in the memory cell region 1001 and the peripheral circuit region 1002 as a stopper. At this time, the silicon nitride film 204 is preferably formed in approximately a uniform height.

In the memory cell region 1001, the buried insulation film 115 is polished so that the silicon nitride film 204 is exposed. Then, as shown in FIG. 16B, the buried insulation film 115 is formed to have approximately the same height as the silicon nitride film 204.

In the peripheral circuit region 1002, the buried insulation film 208 is polished so that the silicon nitride film 204 is exposed. Then, as shown in FIG. 21C, the buried insulation film 208 is formed to have approximately the same height as the silicon nitride film 204.

In steps shown in FIGS. 16C and 22A, the silicon nitride film 204 that was used as a stopper for CMP is removed.

As a result, the above-gate insulation film 203 is exposed in the memory cell region 1001 and the peripheral circuit region 1002. The silicon nitride film 204 is removed by means of wet etching using thermal phosphoric acid, for instance.

A resist pattern is formed to cover the whole surface of the peripheral circuit region 1002 and to expose the above-gate insulation film 203 in the memory cell region 1001. The above-gate insulation film 203 in the memory cell region 1001 is removed with use of this resist pattern as a mask. At this time, the above-gate insulation film 203 is covered with the resist functioning as a mask in the peripheral circuit region 1002. Therefore, the above-gate insulation film 203 is not removed. The above-gate insulation film 203 in the memory cell region 1001 is removed by means of dry etching, for instance. The dry etching conditions are set as follows. For example, the gas flow rates of CF₄, CH₂F₂, and He are set to be 45, 30, and 100 sccm, respectively. The chamber pressure is set to be 10 mTorr (i.e., 1.33 Pa). The RF powers of upper and lower portions are set to be 900 and 80 W, respectively.

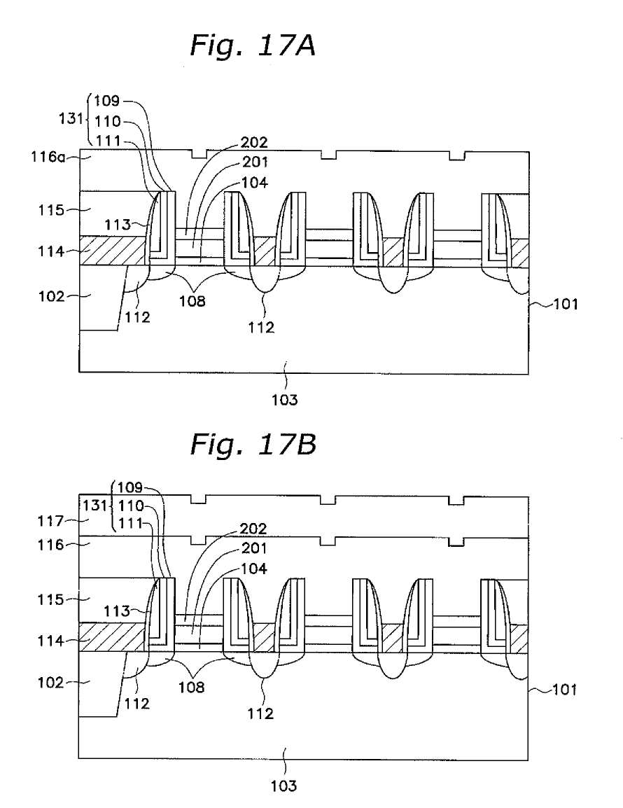

In a step shown in FIG. 17A, a tungsten film 116a with a thickness of 100 nm is formed. The tungsten film 116a is formed on the whole surface of the semiconductor device 101 so that it covers the WSi film 202 and the buried insulation film 115. The tungsten film 116a is formed to fill spaces inside pairs of the sidewall 131 and the sidewall 113 and to cover the WSi film 202. The tungsten film 116a is formed by means of the CVD method, for instance. The conditions of the CVD method are set as follows. For example, the gas flow rates of WF₆, SiH₄, H₂, Ar, N₂ are set to be 22, 10, 400, 250, and 350 sccm, respectively. The chamber pressure is set to be 500 Pa.

In a step shown in FIG. 17B, a silicon oxide film with a thickness of 100 nm formed on the tungsten film 116a is patterned by means of the same method as that used in the step shown in FIG. 7A, and then a hard mask 117 shown in FIG. 17B is formed.

Then, the tungsten film 116a is patterned in a shape of the word line 116 shown in FIG. 1 with use of the hard mask 117 as a mask. Thus, the word line 116 shown in FIGS. 1 and 17B is formed. As a result, as shown in FIG. 19A, portions of the tungsten film 116a that are not covered with the hard mask 117 are removed, and thus the WSi film 202 is exposed. The tungsten film 116a is etched by means of dry etching, for instance. The dry etching conditions are set as follows. For example, the gas flow rates of Cl₂, O₂, CF₄ are set to be 20, 40, and 80 sccm, respectively. The chamber pressure is set to be 5 mTorr (i.e., 0.667 Pa). The RF powers of upper and lower portions are set to be 220 and 75 W, respectively.

In a step shown in FIG. 19B, the hard mask 117 is continuously used as a mask, and the WSi film 202 and the polysilicon film 201 shown in FIG. 19A are removed. At this time, as shown in FIG. 22A, the WSi film 202 is covered with the above-gate insulation film (silicon oxide film) 203 in the peripheral circuit region 1002. Therefore, the WSi film 202 is not removed. Therefore, the WSi film 202 is removed by means of dry etching, for instance. The dry etching conditions are set as follows. For example, the gas flow rates of Cl₂ and O₂ are set to be 20 and 2 sccm, respectively. The chamber pressure is set to be 3 mTorr (i.e., 0.4 Pa). The RF powers of upper and lower portions are set to be 220 and 120 W, respectively. The polysilicon film 106 is etched by means of dry etching under the same condition as that used in the first embodiment, for instance.

In a step shown in FIG. 18, in the region of the word line 116 in the memory cell region 1001, an intermediate insulation film 118 is formed to cover the hard mask 117. In addition, as shown in FIG. 19C, the intermediate insulation film 118 is formed to fill spaces between the sidewalls 131 and to cover the gate insulation film 104, and at the same time as this, to cover the buried insulation film 115. Furthermore, as shown in FIG. 22B, the intermediate insulation film 118 is formed to fill spaces between the sidewalls 206 and to cover the gate insulation film 203, and at the same time as this, to cover the buried insulation film 208. The method for forming the intermediate insulation film 118 is the same as that used in the first embodiment. That is, the intermediate insulation film 118 is formed by means of the CVD method, for instance.

Here, methods for forming contacts 120 and 221 shown in FIG. 1 are hereinafter explained. In the present embodiment, a cross-section of a portion in which a contact hole 120a and the contact 120 are formed is the same as that shown in FIG. 19C. Therefore, in the present embodiment, the intermediate insulation film 118 and the buried insulation film 115 shown in FIG. 8C are also processed in the memory cell region 1001 as with the first embodiment, and thus the contact hole 120a is formed. In addition, the intermediate insulation film 118 and the buried insulation film 208 are processed in the peripheral circuit region 1002. Thus, as shown in FIG. 22B, contact holes 221a to expose portions of the N⁺ diffusion layer 207 are formed. Portions of the intermediate insulation film 118 and the buried insulation films 115 and 208, respectively, are removed by means of dry etching, for instance. The dry etching conditions are set as follows. For example, the gas flow rates of CF₄, CH₂F₂, and He are set to be 45, 30, and 100 sccm, respectively. The chamber pressure is set to be 10 mTorr (i.e., 1.33 Pa). The RF powers of upper and lower portions are set to be 900 and 80 W, respectively.

According to the present embodiment, the same effects as those in accordance with the first embodiment can be obtained. In addition, a transistor in the memory cell region 1001 and the peripheral circuit region 1002 is formed by a common multi-layer wiring film comprised of the gate insulation film 104, the polysilicon film 201, the WSi film 202, the above-gate insulation film 203, and the silicon nitride film 204. Therefore, the number of film forming steps performed for forming a gate will be reduced.

### GENERAL INTERPRETATION OF TERMS

In understanding the scope of the present invention, the term “configured” as used herein to describe a component, section or part of a device includes hardware and/or software that is constructed and/or programmed to carry out the desired function. In understanding the scope of the present invention, the term “comprising” and its derivatives, as used herein, are intended to be open ended terms that specify the presence of the stated features, elements, components, groups, integers, and/or steps, but do not exclude the presence of other unstated features, elements, components, groups, integers and/or steps. The foregoing also applied to words having similar meanings such as the terms, “including,” “having,” and their derivatives. Also, the term “part,” “section,” “portion,” “member,” or “element” when used in the singular can have the dual meaning of a single part or a plurality of parts. Finally, terms of degree such as “substantially,” “about,” and “approximately” as used herein mean a reasonable amount of deviation of the modified term such that the end result is not significantly changed. For example, these terms can be construed as including a deviation of at least ±5% of the modified term if this deviation would not negate the meaning of the word it modifies.

While only selected embodiments have been chosen to illustrate the present invention, it will be apparent to those skilled in the art from this disclosure that various changes and modifications can be made herein without departing from the scope of the invention as defined in the appended claims. Furthermore, the foregoing descriptions of the embodiments according to the present invention are provided for illustration only, and not for the purpose of limiting the invention as defined by the appended claims and their equivalents. Thus, the scope of the invention is not limited to the disclosed embodiments.

What is claimed is:

1. A semiconductor device, comprising:
a semiconductor substrate;
a plurality of first wirings that are disposed above the semiconductor substrate along a first direction;
a diffusion layer that is disposed on the surface of the semiconductor substrate so as to extend along a second direction perpendicular to the first direction, and which comprises a plurality of first diffusion layer portions overlapping with the plurality of first wirings;
a first conductive film that is disposed between adjacent first diffusion layer portions of the plurality of first diffusion layer portions disposed along the plurality of first wirings, respectively, in a layer between the semiconductor substrate and the plurality of first wirings, and configured to be electrically coupled to the plurality of first wirings;
a plurality of sidewall portions, each of which is formed on a lateral side of the first conductive film so as to be disposed between the first conductive film and its adjacent first diffusion layer portion and extend along the diffusion layer; and
a second conductive film that has a predetermined thickness, and is filled in spaces interposed between two adjacent sidewall portions on each of the plurality of first diffusion layer portions so as to extend along each of the plurality of first diffusion layer portions.

2. The semiconductor device according to claim 1, wherein the plurality of sidewall portions are configured to separate the plurality of first diffusion layer portions from each other.

3. The semiconductor device according to claim 2, wherein
two adjacent sidewall portions are configured to surround each of the plurality of first diffusion layer portions; and
the second conductive film is buried in regions surrounded by two adjacent sidewall portions.

4. The semiconductor device according to claim 1, wherein the plurality of sidewall portions comprise a charge storage film, respectively.

5. The semiconductor device according to claim 4, wherein the plurality of sidewall portions comprises a first sidewall portion comprising the charge storage film, and a second sidewall portion that is disposed on the outside of the first sidewall portion and configured to electrically isolate the charge storage film and the second conductive film.

6. The semiconductor device according to claim 1, further comprising a first insulation film that is buried in spaces interposed between two adjacent sidewall portions on the second conductive film and configured to electrically isolate the plurality of first wirings and the second conductive film.

7. The semiconductor device according to claim 1, wherein the plurality of first diffusion layer portions comprise contacts on the outside of the plurality of first wrings through the second conductive film.

8. The semiconductor device according to claim 1, wherein
the first conductive film and the first diffusion layer portions disposed on both sides of the first electrode comprise a gate electrode, and a source/drain of a memory cell transistor, respectively; and
the plurality of first diffusion layer portions and the first conductive film comprise a plurality of bit lines.

9. The semiconductor device according to claim 8, wherein
the semiconductor substrate comprises a memory cell region in which the memory cell transistors are formed and a peripheral circuit region in which peripheral circuit transistors are formed; and
no charge storage film is formed in each of gate electrodes of the peripheral circuit transistors.

10. The semiconductor deice according to claim 8, wherein
the semiconductor substrate comprises a memory cell region in which the memory cell transistors are formed and a peripheral circuit region in which peripheral circuit transistors are formed;
each of gate electrodes of the memory cell transistors do not comprise silicide film; and
each of gate electrodes of the peripheral circuit transistors comprises a silicide film.

11. The semiconductor device according to claim 2, wherein each of the plurality of sidewall portions comprises a charge storage film.

12. The semiconductor device according to claim 3, wherein each of the plurality of sidewall portions comprises a charge storage film.

13. The semiconductor device according to claim 2, further comprising a first insulation film that is buried in spaces interposed between two adjacent sidewall portions on the second conductive film, and configured to electrically isolate the plurality of first wirings and the second conductive film.

14. The semiconductor device according to claim 3, further comprising a first insulation film that is buried in spaces interposed between two adjacent sidewall portions on the second conductive film, and configured to electrically isolate the plurality of first wirings and the second conductive film.

15. The semiconductor device according to claim 2, wherein the plurality of first diffusion layer portions comprise contacts on the outside of the plurality of first wirings through the second conductive film.

16. The semiconductor device according to claim 3, wherein the plurality of first diffusion layer portions comprise contacts on the outside of the plurality of first wirings through the second conductive film.

17. The semiconductor device according to claim 2, wherein
the first conductive film and the first diffusion layer portions disposed on both sides of the first electrode comprise a gate electrode and a source/drain of a memory cell transistor, respectively; and
the plurality of first diffusion layer portions and the first conductive film comprise a plurality of bit lines.

18. The semiconductor device according to claim 3, wherein
the first conductive film and the first diffusion layer portions disposed on both sides of the first electrode comprise a gate electrode and a source/drain of a memory cell transistor, respectively; and
the plurality of first diffusion layer portions and the first conductive film comprise a plurality of bit lines.
